(19) United States
(12) Patent Application Publication
(10) Pub. No.: US 2014/0089574 A1
(43) Pub. Date: Mar. 27, 2014

(54) SEMICONDUCTOR MEMORY DEVICE STORING MEMORY CHARACTERISTIC INFORMATION, MEMORY MODULE AND MEMORY SYSTEM HAVING THE SAME, AND OPERATING METHOD OF THE SAME

(71) Applicant: Samsung Electronics Co., Ltd., Suwon-Si (KR)

(72) Inventors: Young-Soo SOHN, Seoul (KR); Dae-Hyun KIM, Hwaseong-si (KR); Seung-Jun BAE, Hwaseong-si (KR); Tae-young OH, Seoul (KR); Woo-jin LEE, Seoul (KR)

(73) Assignee: Samsung Electronics Co., Ltd., Suwon-Si (KR)

(21) Appl. No.: 14/018,927

(22) Filed: Sep. 5, 2013

(30) Foreign Application Priority Data
Sep. 24, 2012 (KR) 10-2012-0105947

(51) Int. Cl. G11C 7/10

(52) U.S. Cl. CPC G11C 7/1072
USPC 711/105

(57) ABSTRACT

A semiconductor memory device storing memory characteristic information, a memory module including the semiconductor memory device, a memory system, and an operating method of the semiconductor memory device. The semiconductor memory device may include a cell array including a plurality of areas; a command decoder configured to decode a command and generate an internal command; and an information storage unit configured to store characteristic information of at least one of the plurality of areas. When a first command and a first row address accompanying the first command are received, characteristic information of an area corresponding to the first row address is provided to an outside.

### CROSS-REFERENCE TO RELATED APPLICATIONS

This application claims the benefit under 35 U.S.C. §119 of Korean Patent Application No. 10-2012-0105947, filed on Sep. 24, 2012, in the Korean Intellectual Property Office, the disclosure of which is incorporated herein in its entirety by reference.

### BACKGROUND

1. Field

The inventive concepts relates to a semiconductor memory device, and more particularly, to a semiconductor memory device storing memory characteristic information, a memory module and memory system having the same, and an operating method of the same.

2. Description of the Related Art

The capacity and speed of semiconductor devices widely used in high-performance electronic systems have increased. Dynamic random access memory (DRAM), which is an example of a semiconductor device, is volatile memory that determines data according to charges stored in a capacitor. Since the charges stored in the capacitor may leak in various forms over time, the DRAM has a finite data retention characteristic.

As DRAM process scaling has continuously improved, a cell capacitor has continuously become smaller and a retention time for holding data has shortened, and thus, a process throughput has decreased. Although various methods, such as a method of increasing repair resources, have been proposed to address this matter, there is a limitation in improving the process throughput by these methods.

### SUMMARY

One embodiment of the Inventive concepts provide a semiconductor memory device capable of increasing the memory performance affected by a memory cell or a page (a weak cell or a weak page) having a low memory characteristic, a memory module and memory system having the same, and/or an operating method of the semiconductor memory device.

According to example embodiments of the inventive concepts, a semiconductor memory device may include a cell array having a plurality of areas; a command decoder configured to decode a command and generate an internal command; and an information storage unit configured to store characteristic information of at least some of the plurality of areas. When a first command and a first row address accompanying the first command are received, characteristic information of an area corresponding to the first row address may be provided to an outside device.

Example embodiments provide that the cell array may include a dynamic random access memory (DRAM) cell, and the areas are page units that are designated by a row address.

Example embodiments provide that the characteristic information may include address information that represents at least one of the areas of the plurality of areas with a relatively low memory characteristic as compared to a memory characteristic of at least one other area of the plurality of areas.

Example embodiments provide that the characteristic information may further include at least one piece of information from among a data retention characteristic and a write time characteristic of an area corresponding to the address information.

Example embodiments provide that the cell array may include one or more bank, where each bank may include a plurality of sub-banks, and the characteristic information may include information regarding the sub-banks which the respective areas belong.

Example embodiments provide that the characteristic information provided to the outside device may include at least one of a first information representing whether or not the area corresponding to the first row address is a weak area, a second information regarding a memory characteristic of the area, and a third information representing whether or not the sub-bank which the area corresponding to the first row address belongs to is the same as the sub-bank that is previously activated.

Example embodiments provide that the first command may be an active command accompanied by a row address.

Example embodiments provide that the first command may be a complex command that requests at least two memory operations, and the complex command may be accompanied by a row address.

Example embodiments provide that the complex command may be a command for instructing at least one operation from among a write operation, a read operation, a precharge operation, and an active operation to be serially performed.

Example embodiments provide that the first row address may be an address for designating an area to be activated that is next to an area that is currently activated.

Example embodiments provide that the semiconductor memory device may further include a comparison unit configured to compare the first address with the information stored in the information storage unit and output a comparison result; and a delay unit configured to receive the internal command and control delay of the internal command according to the comparison result.

Example embodiments provide that the semiconductor memory device may further include a mode register set (MRS) for setting an amount of delay due to the delay unit.

Example embodiments provide that a second command may be received according to an input timing signal controlled according to the characteristic information provided to the outside device.

According to example embodiments of the inventive concepts, a semiconductor memory device may include a cell array that includes a plurality of areas; a command decoder configured to decode a command and generates an internal command; an information storage unit configured to store address information of at least one of the plurality of areas; a comparison unit configured to compare a received address and the address information stored in the information storage unit and output a comparison result; and a flag generation unit configured to generate a flag representing characteristics of the corresponding area according to the comparison result.

Example embodiments provide that the information storage unit may be configured to store address information of areas with a relatively weak characteristic from among the plurality of areas and store information regarding sub-banks or blocks to which the respective areas belong.

Example embodiments provide that the comparison unit may include a first comparison unit configured to compare the received address and the address information of areas with a relatively weak characteristic and output a comparison result, and a second comparison unit configured to compare a previously accessed area and an area accessed by the received address to determine if the previously accessed area and the area accessed by the received address belong to the same sub-bank or the same block.

Example embodiments provide that the flag generation unit may be configured to generate a flag of a plurality of bits indicating whether or not the area accessed by the received address is a weak area and whether the area that is previously accessed and the area accessed by the received address belong to the same sub-bank or the same block, in response to the comparison result output by the first comparison unit and the comparison result output by the second comparison unit.

Example embodiments provide that the semiconductor memory device may further include a delay unit configured to receive the internal command and control delay of the internal command according to the comparison result, such that a timing of a memory operation due to the internal command is controlled according to the controlled delay.

According to example embodiments of the inventive concepts, a method of operating a semiconductor memory device that includes a cell array that has a plurality of areas is provided. The method include the semiconductor memory device receiving a first command and a first row address accompanying the first command. The semiconductor memory device decodes the first command to generate an internal command. The semiconductor memory device compares the first row address and characteristic information of at least one area of the cell array stored in the semiconductor memory device. The semiconductor memory device outputs characteristic information of an area corresponding to the first row address to an outside device according to a comparison result.

Example embodiments provide that the first command may be a complex command that includes a command for requesting a first memory operation and an active command for activating the area corresponding to the first row address, and the comparing of the first row address may be performed together with the first memory operation.

Example embodiments provide that the method may further include controlling delay of an internal active command that is obtained by decoding the active command according to the comparison result.

The method may further include receiving a second command according to an input timing controlled according to the characteristic information provided to the outside device.

Example embodiments provide that the characteristic information provided to the outside device may include at least one from among first information representing whether or not the area corresponding to the first row address is a weak area, second information regarding a memory characteristic of the area, and third information representing whether or not the sub-bank which the area corresponding to the first row address belongs to is the same as the sub-bank that is previously activated.

According to example embodiments of the inventive concepts, a memory system including a memory controller may include a command generation unit configured to generate a command; a flag receiving unit configured to receive a flag related to characteristic information of a memory; and a scheduler configured to manage an operation for generating the command according to the received flag, such that the flag is received in correspondence to output of a row command accompanying a row address.

Example embodiments provide that the memory system may further include a semiconductor memory device having a cell array that includes a plurality of areas, a command decoder configured to receive and decodes the command to generate an internal command, and an information storage unit configured to store characteristic information of at least some of the plurality of areas. The memory controller may be configured to compare the row address accompanying the row command with the information stored in the information storage unit to generate the flag in response to the reception of the row command.

According to an example embodiment of the inventive concepts, a memory system may include a memory module that includes a semiconductor memory device mounted on a memory board. The memory module may be configured to provide write data to the semiconductor memory device and to receive read data from the semiconductor memory device. The semiconductor memory device configured to receive a first command and a first row address accompanying the first command from the memory module and provide characteristic information of an area corresponding to the first row address to the memory module. The memory system may include a memory controller configured to provide control signals to the memory module for controlling the semiconductor memory device and configured to receive at least the characteristic information from the memory module.

Example embodiments provide the memory module may include a serial-presence detect (SPD) and the characteristic information may be stored in the SPD.

Example embodiments provide that the semiconductor memory device may include a cell array including a plurality of areas and a command decoder configured to decode a command and generate an internal command. The semiconductor device may be configured to store characteristic information of at least one of the plurality of areas in the SPD.

Example embodiments provide that the characteristic information may include a flag, and the flag may represent at least one characteristic of an area corresponding to a comparison of the received address with address information stored in the SPD.

Example embodiments provide that the memory controller is may be configured to provide control signals to the memory module for controlling the SPD and configured to receive data stored in the SPD from the memory module.

### BRIEF DESCRIPTION OF THE DRAWINGS

The above and other features and advantages will become more apparent by describing in detail example embodiments of the inventive concepts with reference to the attached drawings. The accompanying drawings are intended to depict example embodiments of the inventive concepts and should not be interpreted to limit the intended scope of the claims. The accompanying drawings are not to be considered as drawn to scale unless explicitly noted.

FIG. 1 is a block diagram showing an example of a semiconductor memory device and a memory controller, according to an example embodiment of the inventive concepts;

FIG. 2 is a block diagram showing an example of various memory systems, according to an example embodiment of the inventive concepts;

FIG. 3 is a block diagram showing an example of a memory system in which characteristic information is stored in a serial-presence detect (SPD) of a memory module, according to an example embodiment of the inventive concepts;

FIG. 4 is a block diagram showing an example of a semiconductor memory device, according to another example embodiment of the inventive concepts;

FIGS. 5A and 5B are block diagrams showing a detailed operation of the semiconductor memory device shown in FIG. 4, according to an example embodiment of the inventive concepts;

FIGS. 6A and 6B are diagrams showing an example of an operation of a semiconductor memory device that receives a complex command and operates, according to an example embodiment of the inventive concepts;

FIG. 7 is a block diagram showing an example of analyzing characteristic information using a test equipment for a semiconductor memory device, according to an example embodiment of the inventive concepts;

FIG. 8 is a block diagram showing an example of a semiconductor memory device for storing characteristic information, according to an example embodiment of the inventive concepts;

FIGS. 9A to 10B are diagrams showing an example of characteristic information stored in a semiconductor memory device, according to an example embodiment of the inventive concepts;

FIG. 11 is a block diagram showing an example of a memory controller, according to an example embodiment of the inventive concepts;

FIGS. 12A and 12B are diagrams showing an example of transmission of memory characteristic information and a control operation of a semiconductor memory device, according to an example embodiment of the inventive concepts;

FIG. 13 is a diagram showing another example of transmission of characteristic information and a control operation of a semiconductor memory device, according to an example embodiment of the inventive concepts;

FIG. 14 is a diagram showing another example of transmission of characteristic information and a control operation of a semiconductor memory device, according to an example embodiment of the inventive concepts;

FIGS. 15A and 15B are diagrams showing an example of various commands and parameters that are applied to a semiconductor memory device, according to an example embodiment of the inventive concepts;

FIGS. 16A and 16B are diagrams showing another example of transmission of characteristic information and a control operation of a semiconductor memory device, according to an example embodiment of the inventive concepts;

FIG. 17 is a diagram showing another example of transmission of characteristic information and a control operation of a semiconductor memory device, according to an example embodiment of the inventive concepts;

FIGS. 18A and 18B are diagrams showing another example of transmission of characteristic information and a control operation of a semiconductor memory device, according to an example embodiment of the inventive concepts;

FIG. 19 is a flowchart showing an operating method of a semiconductor memory device, according to an example embodiment of the inventive concepts;

FIG. 20 is a flowchart showing a an operating method of a semiconductor memory device, according to another example embodiment of the inventive concepts;

FIG. 21 is a flowchart showing an operating method of a memory controller, according to an example embodiment of the inventive concepts;

FIG. 22 is a block diagram showing an example in which delay of an internal command of a semiconductor memory device is controlled by a mode register set (MRS), according to an example embodiment of the inventive concepts;

FIG. 23 is a block diagram showing an example of a semiconductor memory device that outputs information bits, according to an example embodiment of the inventive concepts;

FIGS. 24 and 25 are block diagrams respectively showing examples of memory controllers, according to an example embodiment of the inventive concepts;

FIG. 26 is a block diagram showing an example of a memory module including a semiconductor memory device, according to an example embodiment of the inventive concepts;

FIG. 27 is a block diagram showing another example of a memory module and a memory system, according to an example embodiment of the inventive concepts;

FIG. 28 is a structure diagram showing a semiconductor memory device, according to another example embodiment of the inventive concepts;

FIG. 29 is a diagram showing another example of a memory module including a semiconductor memory device, according to an example embodiment of the inventive concepts;

FIG. 30 is a diagram for describing a memory system including a semiconductor memory device, according to another example embodiment of the inventive concepts; and

FIG. 31 is a block diagram showing a computing system on which a memory system is installed, according to an example embodiment of the inventive concepts.

### DETAILED DESCRIPTION OF THE EMBODIMENTS

Hereinafter, the inventive concepts will be described more fully with reference to the accompanying drawings, in which exemplary embodiments of the inventive concepts are shown. The inventive concepts may be embodied in many different forms and should not be construed as limited to the exemplary embodiments set forth herein. Rather, these embodiments are provided so that this disclosure will be thorough and complete, and will fully convey the scope of the inventive concepts to those skilled in the art.

It will be understood that, although the terms ‘first’, ‘second’, ‘third’, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concepts. For example, a first element may be designated as a second element, and similarly, a second element may be designated as a first element without departing from the teachings of the inventive concepts.

Unless otherwise defined, all terms (including technical and scientific terms) used herein have the same meaning as commonly understood by one of ordinary skill in the art to which this inventive concepts belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. As used herein, the term “and/or” includes any and all combinations of one or more of the associated listed items. Expressions such as “at least one of,” when preceding a list of elements, modify the entire list of elements and do not modify the individual elements of the list.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof Since Dynamic Random Access Memory (DRAM) as a semiconductor memory device has a finite data retention characteristic, even in a case of a normal cell, if a time defined in a specification has elapsed, the validity of data in the cell may not be guaranteed. A refresh policy is used to maintain data, and accordingly, the DRAM refreshes data stored in a memory cell at every refresh period set as a specification value.

As a DRAM process scaling has been continuously improved, a capacitance value of a cell capacitor has become small, and thus, a refreshing period for maintaining data has been further shortened. Also, as a possibility of generating cells with an increase in a poor recording characteristic, a recording time is increased. Thus, an unsatisfactory specification may occur, thereby resulting in a decrease in a process yield. Although a method of substituting a redundancy cell for a weak cell has been used, a weak cell may have the same or similar memory characteristic as a redundancy cell or a normal cell, and thus, the method has a limited efficiency. Hereinafter, exemplary embodiments in which a semiconductor memory device stores memory characteristic information and a memory operation is managed by using the memory characteristic information will be described.

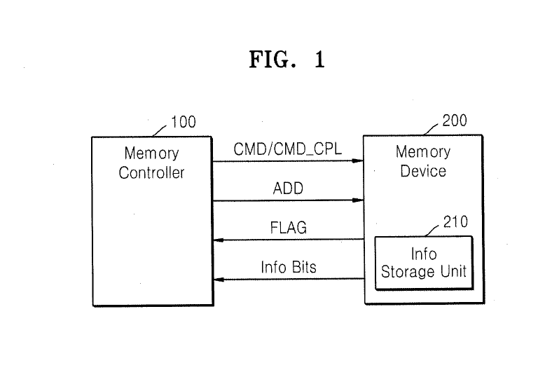

FIG. 1 is a block diagram showing an example of a semiconductor memory device 200 and a memory controller 100, according to an example embodiment of the inventive concepts. As shown in FIG. 1, the memory controller 100 and the semiconductor memory device 200 may constitute a memory system, and the memory controller 100 provides various control signals to the semiconductor memory device 200 to control memory operations. For example, the memory controller 100 provides a command CMD/CMD_CPL and an address ADD to the semiconductor memory device 200 to access data of a cell array (not shown). The command CMD/CMD_CPL may include commands related to various memory operations such as data reading/writing. Also, when the semiconductor memory device 200 includes a DRAM cell, DRAM may perform various unique operations, for example, a refresh operation for refreshing a memory cell.

The semiconductor memory device 200 includes an information storage unit 210 that stores memory characteristic information. The information storage unit 210 may include storage means that stores data in a volatile or non-volatile manner. For example, the information storage unit 210 may include a fuse array (or antifuse array) for storing information in a non-volatile manner.

In various embodiments, the information storage unit 210 may store various pieces of information regarding a characteristic of the semiconductor memory device 200. For example, a cell array included in the information storage unit 210 may include a plurality of areas, where information stored in the information storage unit 210 may be a memory characteristic of each area. Also, the areas of the cell array may be defined in various ways. For example, the cell array may include a plurality of pages that are selected in response to a row address, and the areas may be defined as pages. Each of the areas may include a plurality of memory cells, and as characteristic information regarding each area, a characteristic of the memory cell having the weakest characteristic from among the plurality of memory cells may be stored as characteristic information regarding the corresponding area.

In alternate embodiments, the information storage unit 210 may store address information of the areas having a relatively weak memory characteristic from among the areas included in the cell array. Accordingly, by matching an address ADD of the area to be accessed and the address information stored in the information storage unit 210, it may be determined whether a weak area (for example, weak cell or weak page) of the area corresponding to the address ADD exists, and the semiconductor memory device 200 may provide a flag FLAG signal having information representing that the area to be accessed is a weak area.

The semiconductor memory device 200 may provide the characteristic information stored in the information storage unit 210 to the memory controller 100 in response to a request from the memory controller 100. The memory controller 100 may generate the command CMD/CMD_CPL according to a combination of various signals (for example, /CKE, /CS, /RAS, /CAS, /WE, etc.), and the semiconductor memory device 200 may provide the characteristic information to the memory controller 100 in response to at least one command among the received various signals of CMD/CMD_CPL. The address ADD may be provided to the semiconductor memory device 200 in association with the command CMD/CMD_CPL, and the semiconductor memory device 200 may provide the characteristic information based on the received address ADD to the memory controller 100.

Hereinafter, detailed operations of the memory controller 100 and the semiconductor memory device 200 according to an example embodiment of the inventive concepts will be described. For convenience of description, it is assumed that the area of the cell array is defined as a page in the information storage unit 210, the characteristic information based on the page is stored in the information storage unit 210, and the semiconductor memory device 200 provides the characteristic information regarding a page that is requested to be accessed to the memory controller 100. However, embodiments of the inventive concepts are not limited thereto, and the above-described area may be defined as any of various other units such as a cell unit, a block, a sub-bank, a bank, and/or other like units.

The semiconductor memory device 200 provides the characteristic information to the memory controller 100 in response to a predetermined command CMD/CMD_CPL. In the commands shown in FIG. 1, when the command CMD is referred to as a normal command and the command CMD_CPL is referred to as a complex command, the semiconductor memory device 200 may provide the characteristic information in response to at least one specific command from among various normal commands CMD. For example, various normal commands are predefined for various memory operations, and some of the various normal commands CMD may be accompanied by the address ADD. For example, the semiconductor memory device 200 may provide the characteristic information regarding the page to be accessed to the memory controller 100 in response to the normal command CMD accompanied with the row address.

In addition, the complex command CMD_CPL is a command that requests two or more memory operations to be performed and may be newly defined by consultation between the memory controller 100 and the semiconductor memory device 200. The semiconductor memory device 200 may provide the characteristic information to the memory controller 100 in response to the complex command CMD_CPL. At least some of the complex commands CMD_CPL may be accompanied with the address ADD. For example, the semiconductor memory device 200 may provide the characteristic information regarding the page to be accessed to the memory controller 100 with reference to the received address ADD. As described above, when the complex command CMD_CPL is accompanied by the row address, the semiconductor memory device 200 may provide the characteristic information to the memory controller 100 that corresponds with the row address.

As the characteristic information provided to the memory controller 100, the semiconductor memory device 200 may provide the flag FLAG including a result of matching between addresses or information bits Info Bits having information representing a characteristic value of the page to be accessed to the memory controller 100. The address of the page to be accessed and the address of the weak page stored in the information storage unit 210 are compared with each other, and the flag FLAG may be provided to the memory controller 100 based on a comparison result. In addition, at least one bit value representing memory characteristic of the weak page may be stored in the information storage unit 210, and when the page to be accessed is a weak page, the information bits Info Bits of the corresponding weak page may be provided to the memory controller 100. The information bits Info Bits may be information representing a data retention characteristic, a data write time, and other parameter of the page. As described above, the flag FLAG or the information bits Info Bits are information representing characteristics of the page to be accessed, and the memory controller 100 may manage a memory operation of the corresponding page with reference to characteristic information.

In the above-described example, although a case where the provided characteristic information includes the flag FLAG and the information bits Info Bits has been presented, embodiments of the inventive concepts are not limited thereto. For example, the flag FLAG may include a plurality of bits, and the flag FLAG may include a result of matching between addresses and information bits representing memory characteristics of a page to be accessed.

As another example, the cell array of the semiconductor memory device 200 may include a plurality of sub-banks. In the same sub-bank, one word line (or row) is selectively activated, while rows of different sub-banks may be simultaneously activated. The information storage unit 210 may store information representing in which sub-bank each page is included, and may provide to the memory controller 100 information, as the characteristic information, representing a relationship between a previously accessed page and a page to be currently accessed. For example, the information storage unit 210 may provide to the memory controller 100 information representing whether the previously accessed page and the page to be currently accessed are included in the same sub-bank. In other words, the information representing whether the previously accessed page and the page to be currently accessed are included in the same sub-bank may be further included in the FLAG or the information bits Info Bits and may be provided to the memory controller 100.

In the above-described example, where information regarding the sub-bank is stored has presented, rows belonging to different blocks may be simultaneously activated according to designs. In other words, one bank includes a plurality of blocks, and pages belonging to different blocks may be simultaneously selected. In this case, the information storage unit 210 may store information representing in which block each page is included, and may provide to the memory controller 100 information representing whether a previously accessed page and a page to be currently accessed are included in the same sub-bank.

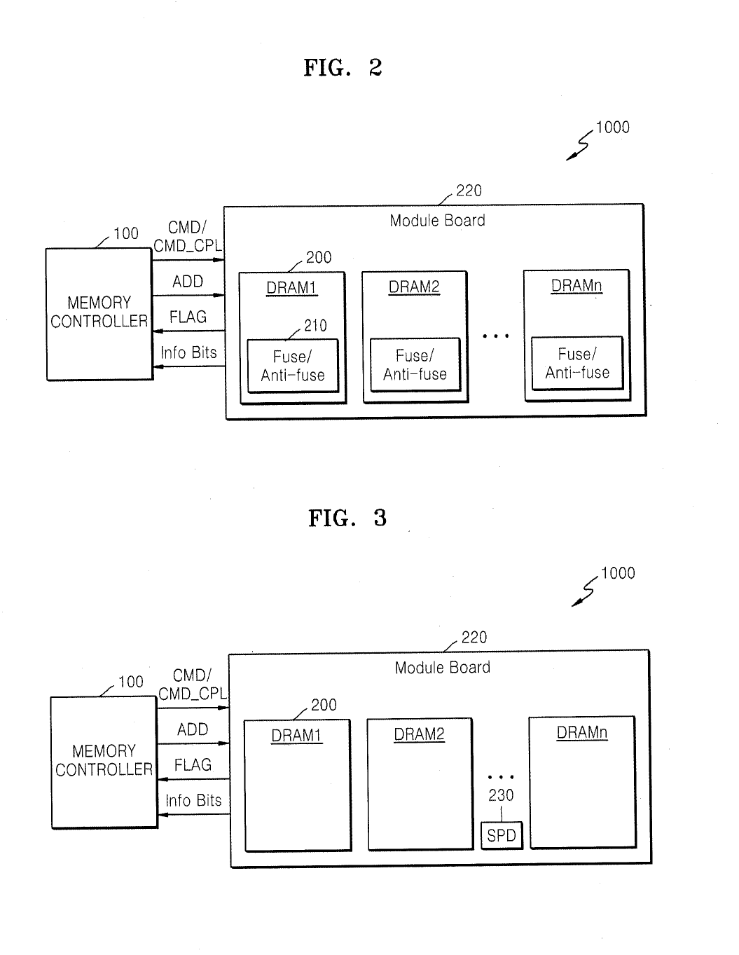

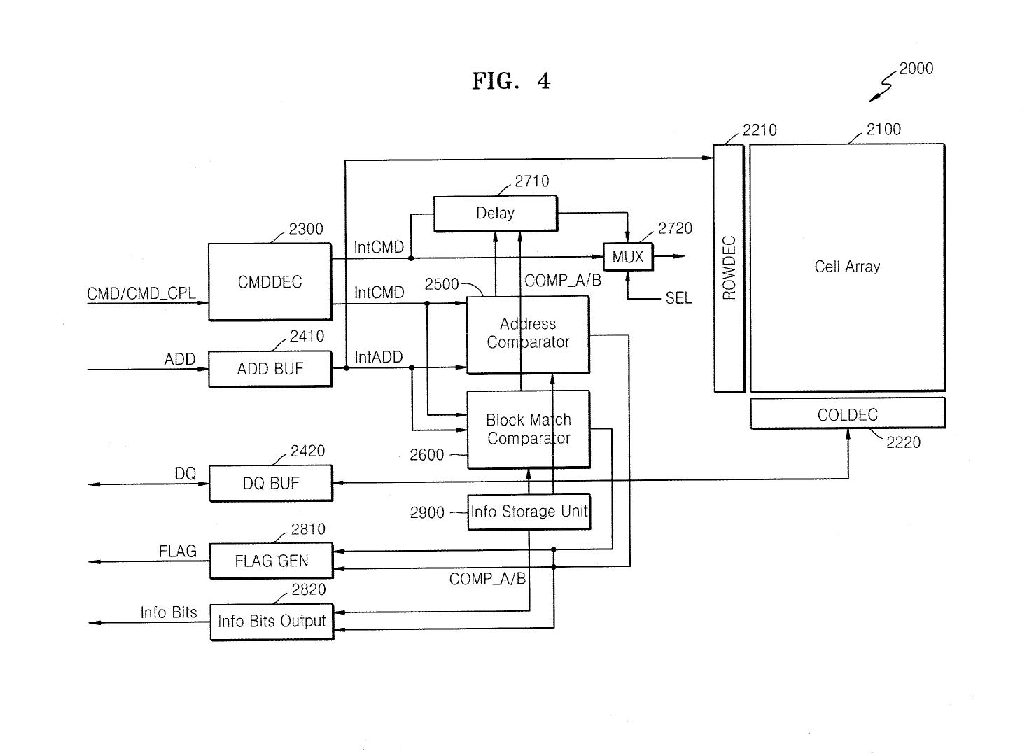

FIGS. 2 and 3 are block diagrams showing examples of various memory systems 1000, according to an example embodiment of the inventive concepts. As shown in FIG. 2, the memory system 1000 includes the memory controller 100 and a memory module 220. Also, the memory module 220 may include at least one semiconductor memory device 200 that is mounted on a module board, and the semiconductor memory device 200 may be a DRAM chip, for example. The semiconductor memory device 200 may include the information storage unit 210 as described above, and the information storage unit 210 may be configured as a non-volatile memory such as a fuse array or an antifuse array.

The memory controller 100 provides various signals for controlling the semiconductor memory device 200, for example, the commands CMD/CMD_CPL and the address ADD, to the memory module 220, provides write data to the semiconductor memory device 200 by communicating with the memory module 220, or receives read data from the semiconductor memory device 200. The address ADD may include a chip ID for selective operations for a plurality of DRAM chips, and the address ADD may include a row address and a column address for selecting rows and columns of the selected DRAM chip. The semiconductor memory device 200 includes a cell array that may include a plurality of areas. For example, the cell array may include a plurality of memory banks, and each Memory bank may include a plurality of pages. The page may be defined as a unit for storing data that moves from a bank to a bit line sense amplifier when one RAS active command is applied.

As described above, the memory controller 100 provides various commands CMD/CMD_CPL to the memory module 220, and characteristic information of the area of the cell array is provided to the controller 100 in response to at least one of the various commands CMD/CMD_CPL. The characteristic information may include the flag FLAG and/or the information bits Info Bits, and the information storage unit 210 may store memory characteristic information, such as address information of the weak cell (or weak page) of the cell array, data retention of the weak cell (or weak page), or a write time, information regarding the sub-bank, and the like. Meanwhile, although a case where the information storage unit 210 stores characteristics such as data retention or a write time of the weak cell (or weak page) has been described, characteristic information of all areas of the cell array may be stored in the information storage unit 210, and information regarding the memory cell or page to be accessed may be provided regardless of whether or not the cell or page is weak.

FIG. 3 is a block diagram showing an example of the memory system 1000 in which characteristic information is stored in a serial-presence detect (SPD) 230 of the memory module 220, according to an example embodiment of the inventive concepts. When the memory module 220 is configured as a registered dual in-line memory module (RDIMM), which is a module for a server, the SPD 230 that stores information regarding the corresponding module and/or information regarding the semiconductor memory device 200 in a non-volatile form may be installed in the memory module 220. The SPD 230 may include a non-volatile memory and may store various pieces of information regarding the semiconductor memory device 200 (for example, a number of row and column addresses, a data width, a number of ranks, a memory intensity for each rank, a number of DRAM chips, a memory intensity for each DRAM chip, and the like) or characteristic information that is analyzed in a test stage of the semiconductor memory device 200. During an initial operation of the memory system 1000, the various pieces of information stored in the SPD 230 may be provided to the memory controller 100. In addition, as in the above-described embodiment, the characteristic information stored in the SPD 230 may be provided to the memory controller 100 in response to the commands CMD/CMD_CPL from the memory controller 100. In FIGS. 2 and 3, characteristics of the cell array that are stored in the information storage unit 210 or the SPD 230 may be analyzed by a test operation at the time of manufacture of the semiconductor memory device 200 or the memory module 220, and a result of the analysis may be stored in the information storage unit 210 in a non-volatile manner.

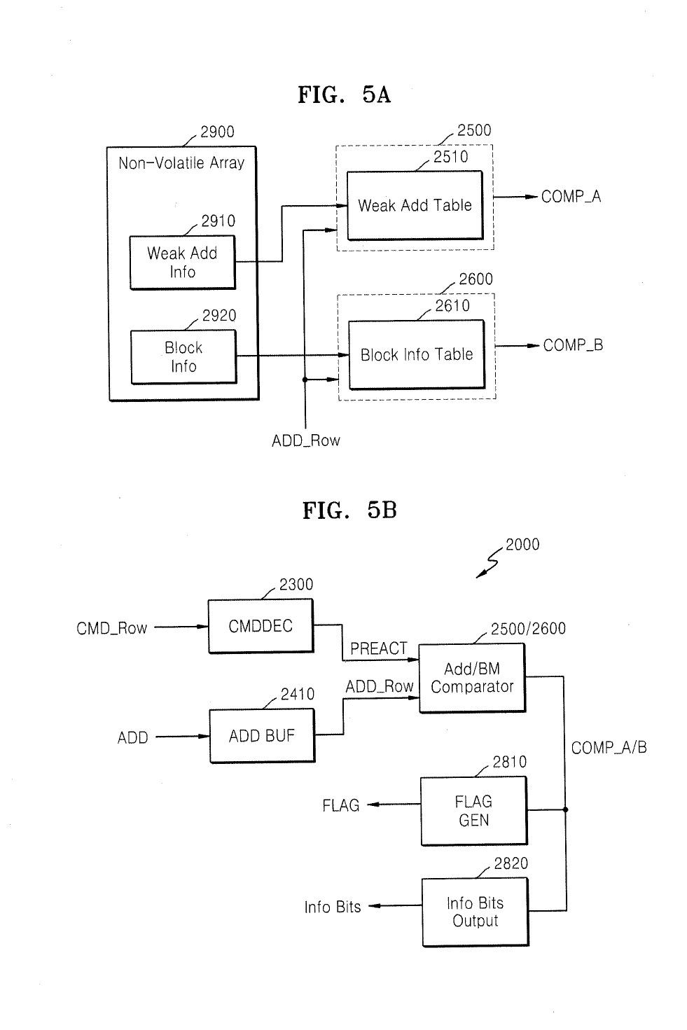

FIG. 4 is a block diagram showing an example of a semiconductor memory device 2000 according to another example embodiment of the inventive concepts. As shown in FIG. 4, the semiconductor memory device 2000 includes a cell array 2100 that may include a plurality of memory cells; a row decoder 2210 that select rows of the cell array 2100 in response to a row address, and a column decoder 2220 that selects columns of the cell array 2100 in response to a column address. The semiconductor memory device 2000 may also include a command decoder 2300 that receives and decodes the command CMD/CMD_CPL to generate an internal command Int CMD, an address buffer 2410 that receives the address ADD from an outside source, and a data buffer 2420 for inputting/outputting data.

Also, according to an example embodiment of the inventive concepts, the semiconductor memory device 2000 may further include an information storage unit 2900 that stores characteristic information of the cell array 2100, an address comparison unit 2500, and a block match comparison unit 2600 that perform a comparison operation for providing the characteristic information. When word lines of different blocks are simultaneously activated, a block matching operation may be performed, but when the word lines of the different sub-banks are simultaneously activated, the block match comparison unit 2600 may be referred to as a sub-bank match comparison unit.

In addition, various operations of the semiconductor memory device 2000 may be controlled according to an address comparison result COMP_A and/or a block match result COMP_B. For example, the semiconductor memory device 2000 may further include a delay unit 2710 that delays and outputs the internal command Int CMD and a selection unit 2720 that selectively outputs the internal command Int CMD and the delayed internal command Int CMD. The selection unit 2720 may be configured as a multiplexer that operates in response to a selection signal SEL, and the selection signal SEL may be generated according to the address comparison result COMP_A and/or the block match result COMP_B. Furthermore, the semiconductor memory device 2000 may further include a flag generation unit 2810 that generates the flag FLAG according to the comparison results COMP_A/B and an information bit output unit 2820 that provides the information bits Info Bits to an outside device.

The above-described comparison operation and an output operation of the flag FLAG/the information bits Info Bits may be performed in response to the command CMD/CMD_CPL. Accordingly, the internal command Int CMD from the command decoder 2300 may be provided to the address comparison unit 2500 and the block match comparison unit 2600. The characteristic information stored in the information storage unit 2900 may be loaded to the address comparison unit 2500 and the block match comparison unit 2600, and the address comparison unit 2500 and the block match comparison unit 2600 may respectively output the comparison results COMP_A/B through the comparison operation based on an internal address Int ADD.

The output operation of the characteristic information may be performed in response to a specific command. For example, the output operation of the characteristic information may be performed in response to some of the predefined various commands CMD. Other pieces of information may be provided to the semiconductor memory device 2000 in association with the command CMD. For example, the output operation of the characteristic information may be performed in response to the command CMD accompanied with the row address. As an example of the command CMD, when an active command ACT for activating rows is received, the comparison operation and the output operation of the characteristic information may be performed using the internal command Int CMD that has decoded the active command ACT and a row address accompanied by the active command ACT.

In addition, as described above, anew command may be defined between the semiconductor memory device 2000 and the memory controller. For example, the complex command CMD_CPL that requests for two or more memory operations may be defined. The complex command CMD_CPL may also be accompanied with the row address, and the semiconductor memory device 2000 may perform the comparison operation and the output operation of the characteristic information using the internal command Int CMD that has decoded the complex command CMD_CPL and the row address accompanied by the complex command CMD_CPL. The complex command CMD_CPL is a command that requests for various memory operations, and may be a command requesting, for example, to successively perform a precharge operation and an active operation.

The address comparison unit 2500 performs a comparison operation using the internal address Int ADD corresponding to a page to be currently accessed. For example, the comparison result COMP_A representing whether the page to be currently accessed is a weak page is output by comparing the internal address Int ADD with information corresponding to the weak page. Also, the block match comparison unit 2600 determines whether the page to be currently accessed is a weak page and whether the previously accessed page is included in the same block (or the same sub-bank) and outputs the comparison result COMP_B.

Meanwhile, the flag generation unit 2810 generates and outputs the flag FLAG according to the comparison results COMP_A/B so that it may be determined whether or not the page to be accessed by the memory controller is weak and whether the page to be accessed by the memory controller and the previously accessed page are included in the same block. Also, the information bit output unit 2820 outputs the information bits Info Bits according to the comparison results COMP_A/B so as to determine memory characteristics (for example, a data retention characteristic, a write time characteristic, and the like) of the page to be accessed by the memory controller. Although the address comparison unit 2500 and the block match comparison unit 2600 are configured as individual components in FIG. 4, in various embodiments, the address comparison unit 2500 and the block match comparison unit 2600 may be a single comparison block that performs various comparison operations.

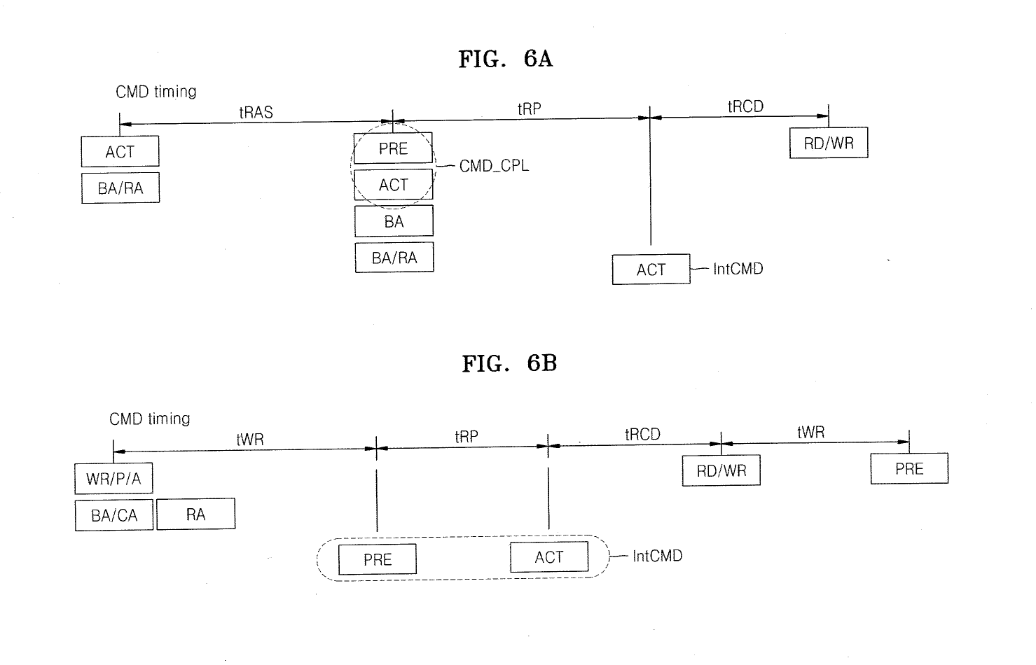

FIGS. 5A and 5B are block diagrams showing a detailed operation of the semiconductor memory device 2000 shown in FIG. 4, according to an example embodiment of the inventive concepts. As shown in FIG. 5A, the information storage unit 2900 may be configured as a non-volatile array, and includes a first area 2910 where address information of the weak area is stored and a second area 2920 where information regarding a block (or sub-bank) is stored. During system driving, information stored in the information storage unit 2900 may be loaded to a table 2510 included in the address comparison unit 2500 and a table 2610 included in the block match comparison unit 2600.

When the comparison operation is performed in response to a command accompanied with the row address, the row address ADD_Row accompanied by the command is provided to both the address comparison unit 2500 and the block match comparison unit 2600 and is compared with various pieces of information stored in the tables 2510 and 2610.

Meanwhile, as shown in FIG. 5B, the address comparison unit 2500 and the block match comparison unit 2600 may operate in response to a specific command. For example, the comparison operation may be performed in response to the command accompanied with the row address (hereinafter, row command CMD_Row), and the row address ADD_Row accompanied by the row command CMD_Row is provided to the address comparison unit 2500 and the block match comparison unit 2600. For example, the row command CMD_Row may be a complex command that commands a precharge operation and an active operation, and an internal command PREACT from the command decoder 2300 may be provided to the address comparison unit 2500 and the block match comparison unit 2600. The flag FLAG and the information bits Info Bits are output according to the comparison results of the address comparison unit 2500 and the block match comparison unit 2600.

Although an example is shown in FIG. 5A in which address information or block information (or sub-bank information) of the above-described weak area is stored in a non-volatile array, embodiments of the inventive concepts is not limited thereto. For example, at least one of generation of the address information and generation of the block information of the weak area may be embodied in a different manner. For instance, the block information may be generated by a state machine (for example, finite state-machine) and provided to the block match comparison unit 2600.

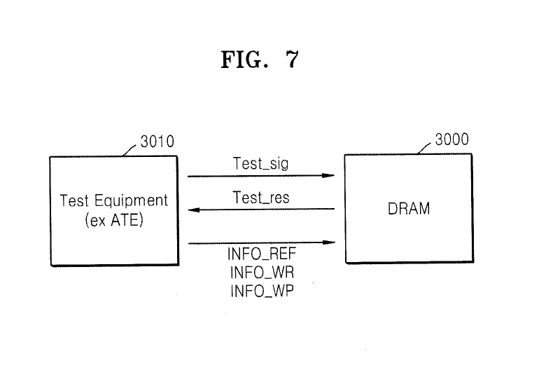

FIGS. 6A and 6B are diagrams showing an example of an operation of the semiconductor memory device that receives a complex command and operates, according to an example embodiment of the inventive concepts. FIG. 6A shows the command CMD_CPL which is a command that requests for a precharge operation and an active operation, according to an example embodiment. FIG. 6B shows the complex command CMD_CPL which is a command that requests for a write operation, a precharge operation, and an active operation, according to an example embodiment.

As shown in FIG. 6A, the semiconductor memory device may receive a bank address BA and a row address RA together with the active command ACT and receives the complex command CMD_CPL after a tRAS corresponding to an active to precharge time. The complex command CMD_CPL, which is a command including a precharge command PRE and the active command ACT, may be accompanied with the bank address BA and the row address RA. Each command may be determined by a combination of various signals (for example, /CKE, /CS, /RAS, /CAS, /WE, etc.), and the complex command CMD_CPL may be newly defined as a combination of signals that are different from the existing precharge command PRE or active command ACT.

When the complex command CMD_CPL is received, the precharge operation is performed. The active operation is automatically performed by the internal command Int CMD after a tRP which is time required for the precharge operation. For example, the precharge operation is performed in correspondence with the bank address BA that is received in association with the complex command CMD_CPL, and an operation due to an internal active command ACT is performed according to command decoding and a delay operation of the semiconductor memory device. An area corresponding to the bank address BA, which is received in association with the complex command CMD_CPL, and the row address RA is selected by the internal active command ACT. Thereafter, a command that is accompanied with a column address (hereinafter, column command) may be input after an RAS to CAS delay tRCD, and a read/write command RD/WR may be received, for example.

Meanwhile, as shown in FIG. 6B, the complex command CMD_CPL may be a command including an auto precharge command WR/P and the active command ACT after a write. In various embodiments, a command may be received in which the auto precharge command WR/P and the active command ACT are combined with each other after a read as the complex command CMD_CPL (not shown). The complex command CMD_CPL may be accompanied with the bank address BA and the row/column address RA/CA. For example, the bank address BA and the column address CA for auto precharge after a write may be received, and the row address RA for the active operation may be accompanied. Although an example is shown in which the column address CA and the row address RA are sequentially received in consideration of a number of address pins of the semiconductor memory device, in various embodiments the column address CA and the row address RA may be simultaneously received.

When the complex command CMD_CPL is received, a write (or read) operation is performed, and a precharge operation is performed by the internal precharge command PRE as the internal command Int CMD after a time tWR which is time required for a recording operation. Also, an active operation is automatically performed by the internal active command ACT as the internal command Int CMD after a tRP which is time required for the precharge operation. As described above, rows that are activated by the automatically performed active operation may correspond to the row address RA that is received in association with the complex command CMD_CPL.

Although only some complex commands CMD_CPL are shown in the example embodiments of FIGS. 6A and 6B, various complex commands CMD_CPL, may be defined in other embodiments. For example, the complex command CMD_CPL may be defined by combining the active command ACT activating the rows with an active command ACT for another memory operation, and when receiving the complex command CMD_CPL, the row addresses RA corresponding to the active command ACT may be simultaneously or sequentially received.

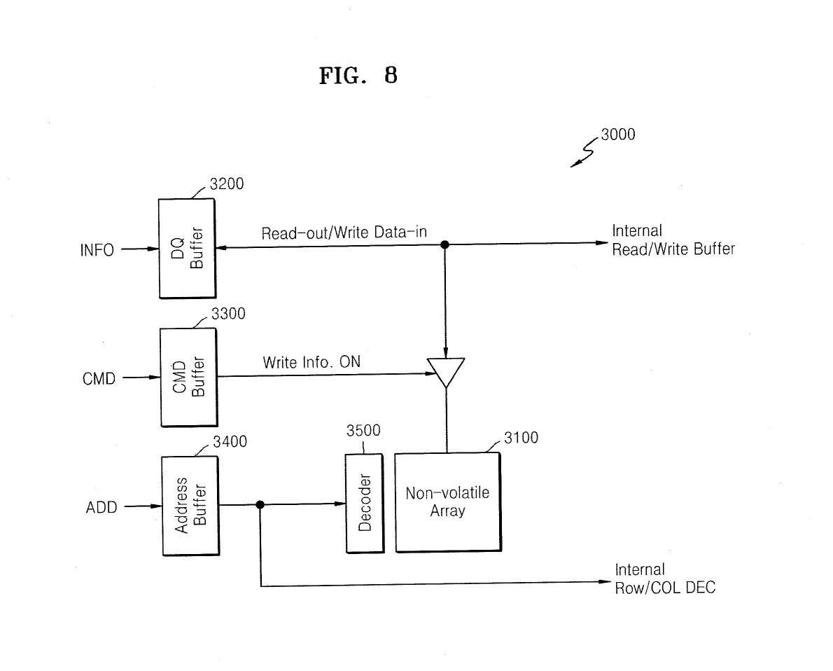

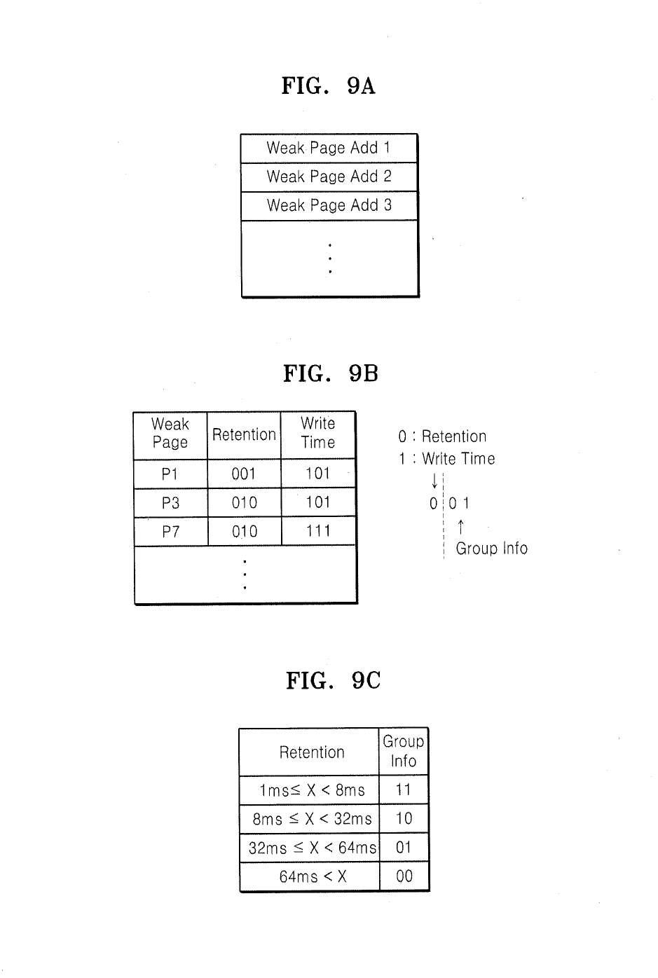

FIG. 7 is a block diagram showing an example of analyzing characteristic information using a test equipment of a semiconductor memory device 3000, according to an example embodiment of the inventive concepts, and FIG. 8 is a block diagram showing an example of the semiconductor memory device 3000 for storing the characteristic information, according to an example embodiment of the inventive concepts. FIG. 7 shows an example in which the semiconductor memory device 3000 is tested by using external test equipment (ATE) 3010. However, the semiconductor memory device 3000 may be tested using any external or internal test equipment.

In order to obtain memory characteristic information for a plurality of areas (for example, pages) of a cell array included in the semiconductor memory device 3000, the test equipment 3010 provides various test signals Test_sig to the semiconductor memory device 3000. The various test signals Test_sig may include a command, an address, and a data signal for accessing the plurality of areas of the cell array. The test equipment 3010 receives a test result Test_res from the semiconductor memory device 3000. For example, the data signal from the test equipment 3010 may be stored in the cell array, and read data that reads the data signal stored in the cell array may be provided as the test result Test_res to the test equipment 3010.

The test equipment 3010 analyzes the test result Test_res and determines a memory characteristic for the areas of the cell array. As the memory characteristic, the test equipment 3010 may determine an address of a relatively weak area or a data retention characteristic of each area, or may determine characteristics related to a memory operation, for example, a write time of data, and/or the like. Also, the memory characteristic may be classified into a plurality of groups according to a value thereof, and it may be determined Which group of the groups the memory characteristic of each area is included. The test equipment 3010 provides various pieces of information INFO_REF, INFO_WR, and INFO_WP such as a weak page address, a retention characteristic, or a write time to the semiconductor memory device 3000 to store the characteristic information according to the test result in the semiconductor memory device 3000.

As shown in FIG. 8, the semiconductor memory device 3000 includes a non-volatile array 3100, a data buffer 3200, a command decoder 3300, an address buffer 3400, and a decoder 3500 for storing the characteristic information. The non-volatile array 3100 may be configured using a fuse array, an antifuse array, and/or any other form of non-volatile storage. The decoder 3500 may be included to select an access location of the non-volatile array 3100 for storing information.

Various pieces of characteristic information INFO from the test equipment may be provided into the semiconductor memory device 3000 via the data buffer 3200. During a normal operation, read or write data is transmitted via the data buffer 3200, while during a test operation, information to be stored in the non-volatile array 3100 may be provided via the data buffer 3200. Also, the command CMD for commanding the non-volatile array 3100 to store information may be provided to the command decoder 3300, and the address ADD for designating a location where the information is to be stored may be input via the address buffer 3400.

According to an example embodiment, the address ADD for storing information in the non-volatile array 3100 may designate each area of the semiconductor memory device 3000, and memory characteristic information INFO corresponding to the address ADD may be information representing a memory characteristic of the corresponding area.

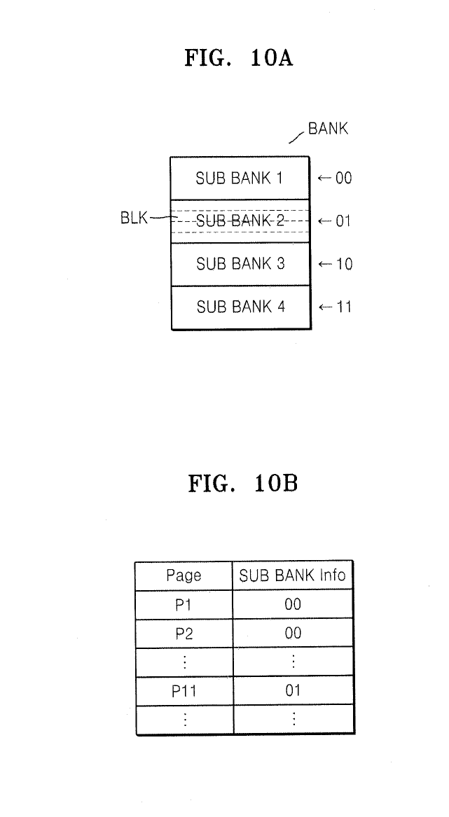

FIGS. 9A to 10B are diagrams showing an example of characteristic information stored in a semiconductor memory device, according to an example embodiment of the inventive concepts. Hereinafter, an area will be assumed to be a page.

As shown in FIG. 9A, a memory characteristic for areas of a cell array of the semiconductor memory device may be stored in a non-volatile array 3100A, according to an example embodiment. For example, among pages of the cell array, pages having a relatively low characteristic, such as a data retention characteristic, or a write time, are determined, and address (for example, row address) information of pages having a low characteristic may be stored in the non-volatile array 3100A. If an address of a page to be accessed is received, the received address is compared with a plurality of pieces of the address information stored in the non-volatile array 3100A, and a flag representing that the corresponding page is a weak page may be generated according to a comparison result thereof.

Meanwhile, FIG. 9B shows an example in which the address information of the weak pages and the memory characteristic information of each weak page are stored in the non-volatile array 3100A, according to an example embodiment. For example, if first, third, and seventh pages P1, P3, and P7 are weak pages, information for each weak page, such as such as a data retention characteristic or a write time, may be stored. Also, each information, such as a data retention characteristic or a write time, may have one or more bit values, and any one bit (for example, a most significant bit (MSB)) may represent what memory characteristic the corresponding information is. In addition, the remaining bits may represent a memory characteristic of the corresponding weak area. For example, the memory characteristic is grouped for each predetermined range, and the remaining bits may have a value that designates a group.

FIG. 9C shows an example in which a data retention characteristic is grouped, according to an example embodiment. For instance, an example is shown in which group information of a page with a data retention characteristic of equal to or greater than 1 ms and less than 8 ms corresponds to a bit value of 11, group information of a page with a data retention characteristic of equal to or greater than 8 and less than 32 ms corresponds to a bit value of 10, group information of a page with a data retention characteristic of equal to or greater than 32 and less than 64 ms corresponds to a bit value of 01, and group information of a page with a data retention characteristic of equal to or greater than 64 ms corresponds to a bit value of 00. Accordingly, the memory characteristic information of the corresponding page may be determined using the information shown in FIG. 9B.

Meanwhile, FIG. 10 shows an example in which sub-bank information is stored in a non-volatile array 3100B, according to an example embodiment. As shown in FIG. 10A, the cell array of the semiconductor memory device may include a plurality of banks, and each bank may include a plurality of sub-banks. FIG. 10A shows an example in which one bank BANK includes four sub-banks SUB-BANK1 to SUB-BANK4 and bit values representing the sub-banks are 00, 01, 10, and 11, respectively. Also, as shown in FIG. 10A, each sub-bank SUB-BANK may include a plurality of blocks, and when rows of different blocks may be simultaneously activated, information regarding the blocks may be stored in the non-volatile array 3100B.

FIG. 10B shows an example in which sub-bank information SUB-BANK INFO corresponding to pages is stored in the non-volatile array 3100B, according to an example embodiment. The value 00 is stored as the sub-block information in areas corresponding to a predetermined range, and the value 01, 10, or 11 may be stored in areas corresponding to other predetermined ranges.

Although the description of the above-described embodiments of FIGS. 9A to 10B refer to a case in which the address and memory characteristic information are distinguished from the sub-bank information of the weak page, example embodiments are not limited thereto. For example, according to example embodiments of the inventive concepts, any one piece of information may be selectively stored in the non-volatile array. Alternatively, both the memory characteristic information and the sub-block information may be stored in the non-volatile array.

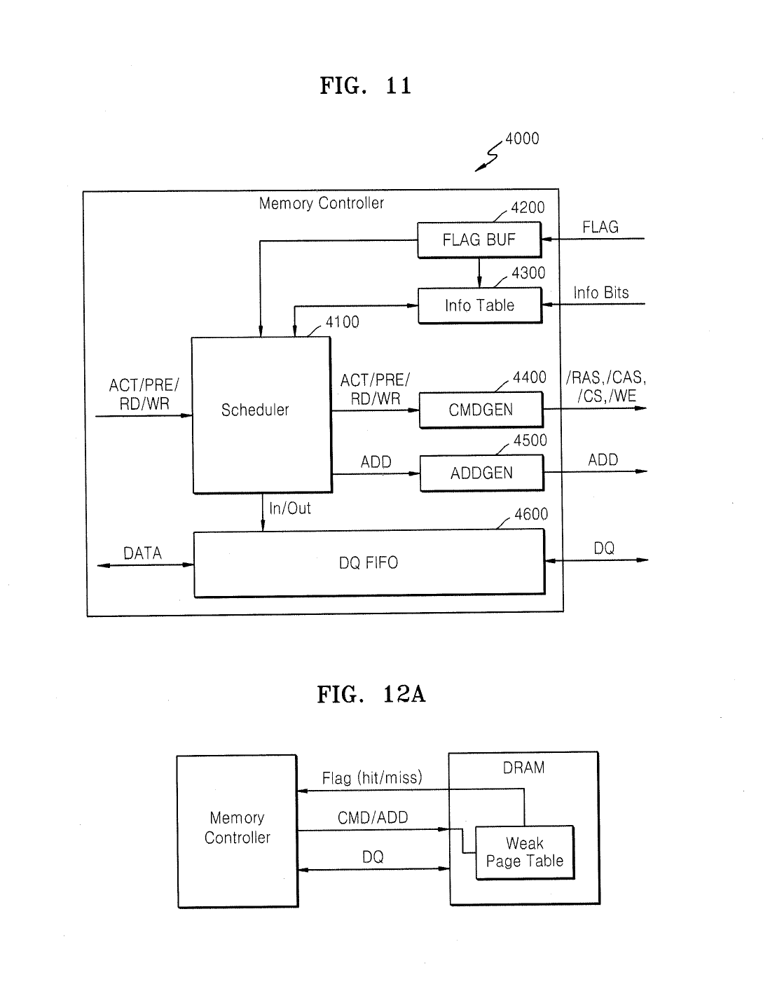

FIG. 11 is a block diagram showing an example of a memory controller 4000, according to an example embodiment of the inventive concepts.

As shown in FIG. 11, the memory controller 4000 includes a scheduler 4100 that manages various signals provided from the semiconductor memory device, a flag receiving unit 4200 that receives characteristic information from the memory device, an information table 4300 that stores characteristic information from the memory device, a command generation unit 4400 that generates a command provided to the semiconductor memory device, and an address generation unit 4500 that generates an address provided to the semiconductor memory device. In addition, the memory controller 4000 includes a data input and output unit 4600 for inputting/outputting data to/from the semiconductor memory device.

The scheduler 4100 may manage provision of various signals, such as commands or addresses, to the semiconductor memory device in consideration of a state of the cell array of the semiconductor memory device and a state of a bus between the semiconductor memory device and the memory controller. For example, the scheduler 4100 manages output of the command generated inside the memory controller 4000, and the command generation unit 4400 generates a combination of various signals /RAS, /CAS, /CS, and /WE corresponding to the command and provides the generated combination as a command to the semiconductor memory device. In addition, the address generation unit 4500 generates and outputs the address ADD for designating an area to be accessed of the semiconductor memory device.

The scheduler 4100 may manage a generation operation of the command or the address on the basis of the flag FLAG and/or the information bits Info Bits that are received from the semiconductor memory device. When the memory controller 4000 provides a predetermined command, the characteristic information and the flag FLAG are received from the semiconductor memory device. The flag FLAG may have information representing whether an area to be currently accessed corresponds to a weak area or whether the previously accessed area and the area to be currently accessed are included in the same sub-bank. Also, the information bits Info Bits is received that has information regarding the memory characteristic corresponding to the area to be currently accessed.

The memory controller 4000 may control operation parameters of the semiconductor memory device on the basis of the received flag FLAG and/or information bits Info Bits. In addition, when the row command accompanied by the row address, such as the active command ACT or the complex command, is provided, the characteristic information is received from the semiconductor memory device in response to the row command, and thus, characteristics of the corresponding area may be previously determined before performing a memory operation, such as an actual write or read, by providing the column command. Accordingly, the memory controller 4000 may control parameters, such as the RAS to CAS delay tRCD, the write time tWR, or the precharge time tRP, according to characteristics of the corresponding area. For example, the memory controller 4000 may control the parameters by controlling an output timing of a command, an address, or the like.

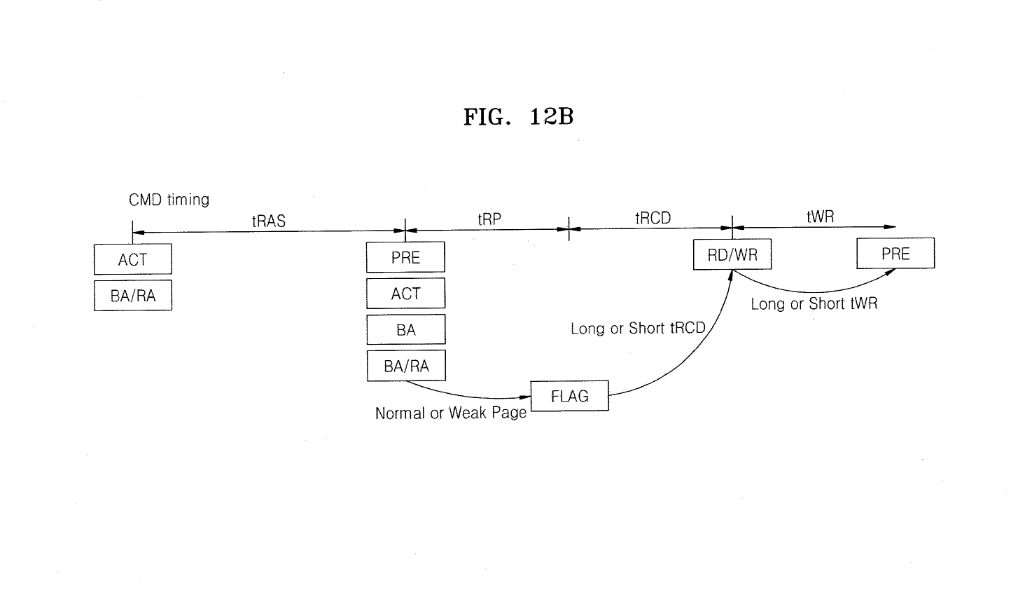

FIGS. 12A and 12B are diagrams showing an example of transmission of memory characteristic information and a control operation of the semiconductor memory device, according to an example embodiment of the inventive concepts. As an example of the semiconductor memory device, a DRAM is used and the memory characteristic information is stored based on a page. Hereinafter, it is assumed that the above-described area is a page.

Referring to FIGS. 12A and 12B, the semiconductor memory device may store address information regarding the weak page in a table, compare the address ADD from an outside source with the address information of the weak page in response to a specific command CMD from the memory controller, and transmit the flag FLAG according to a result of the comparison to the memory controller. For example, when an address that is the same as the address ADD of a page to be accessed is stored in a table as the address of the weak page, the flag FLAG representing a hit may be output to the memory controller, while an address that is the same as the address ADD of a page to be accessed is not stored in a table as the address of the weak page, the flag FLAG representing a miss may be output to the memory controller.

Referring to FIG. 12B, as the complex command, a command including a precharge operation and an active operation may be provided to the semiconductor memory device, and the bank address BA and the row address RA that are accompanied with the complex command may be provided to the semiconductor memory device. In response to the complex command, the precharge operation is performed, and the row address RA to be accessed next is compared with the address information in the table. The flag FLAG is generated according to a comparison result and the generated flag FLAG is provided to the memory controller.

The memory controller receives the flag FLAG, and a memory operation of the semiconductor memory device is controlled on the basis of the received flag FLAG. For example, the memory controller may control the output timing of the command according to a value of the flag FLAG so as to control the operation parameters of the semiconductor memory device. As a comparison result, when the row address RA indicates the weak page, a large RAS to CAS delay tRCD may be applied until the column command such as the read/write command RD/WR is input, or a large write time tWR may be applied until the precharge command is input after the read/write. Accordingly, by securing a sufficient time for various parameters with respect to the weak page, the memory characteristic may be prevented from degrading.

Meanwhile, when the row address RA commands a normal page, the memory controller may progress access with a relatively short timing in accessing the corresponding page. For example, the corresponding page may be accessed by applying the RAS to CAS delay tRCD or the write time tWR that is relatively short.

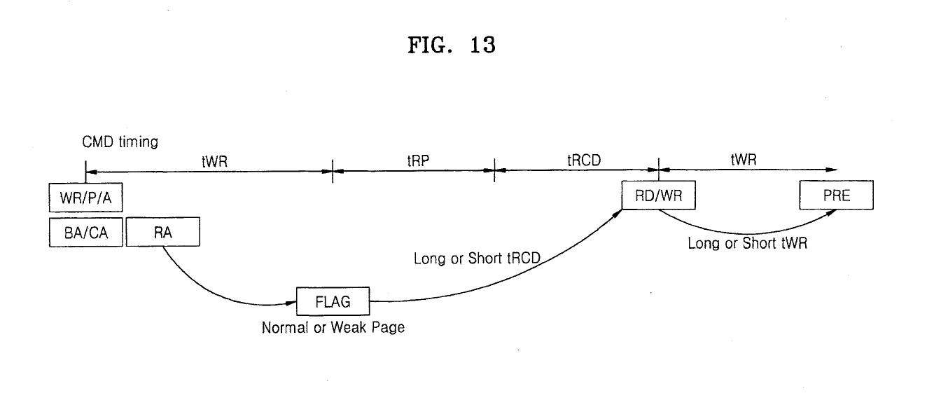

FIG. 13 is a diagram showing another example of the transmission of the characteristic information and the control operation of the semiconductor memory device, according to an example embodiment of the inventive concepts. In the example shown in FIG. 13, as the complex command, a command that requests for the write (or read), the auto precharge operation, and the active operation is provided to the semiconductor memory device, and the bank address BA, the column address CA, and the row address RA that are accompanied with the complex command are provided to the semiconductor memory device. During the write/read and the auto precharge operation, the row address RA to be accessed next is compared with the address information in the table. The flag FLAG is generated according to a comparison result and the generated flag FLAG is provided to the memory controller.

The memory controller receives the flag FLAG, and a memory operation of the memory device is controlled on the basis of the received flag FLAG. In an identical or similar manner to the above-described operation, various parameters such as the RAS to CAS delay tRCD, or the write time tWR may be controlled on the basis of the flag FLAG. For example, when the row address RA commands the weak page, the RAS to CAS delay tRCD or the write time tWR that is relatively large may be applied. On the other band, when the row address RA commands the normal page, the memory controller may access the corresponding page by applying the RAS to CAS delay tRCD or the write time tWR that is relatively short.

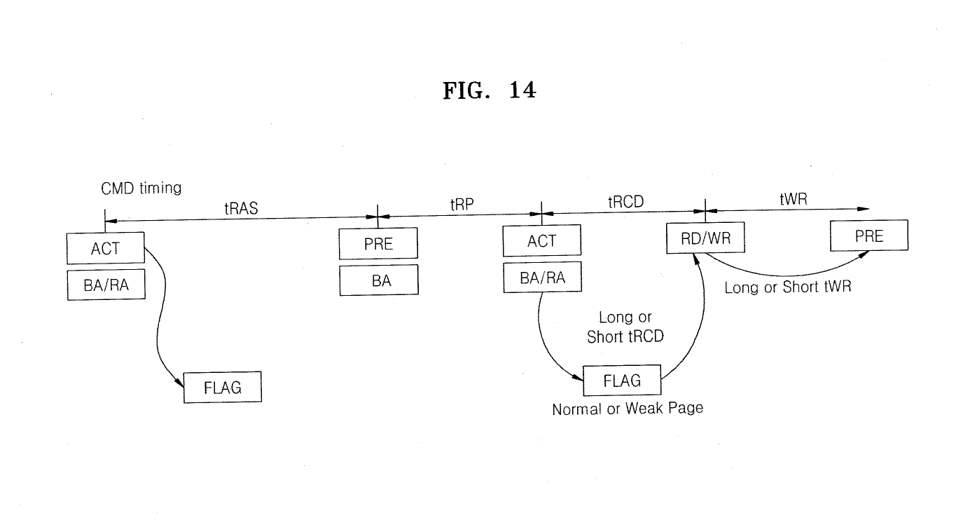

FIG. 14 is a diagram showing another example of the transmission of the characteristic information and the control operation, of the semiconductor memory device, according to an example embodiment of the inventive concepts. FIG. 14 shows an example in which the characteristic information is provided to the memory controller in response to at least some of predefined commands instead of an additionally defined complex command.

The row command may be accompanied with the row address. For example, the active command ACT as the row command may be accompanied with the bank address BA and the row address RA. During an active operation, the row address RA is compared with the address information in the table, and the flag FLAG is generated according to a comparison result and the generated flag FLAG is provided to the memory controller. Also, in an identical or similar manner to those described above, various parameters related to the memory operation may be controlled according to the flag FLAG.

Meanwhile, it may not be necessary for the memory controller to control the operation parameters whenever the flag FLAG is received. For example, the active command ACT and the row address RA may be provided to the semiconductor memory device, and the flag FLAG may be generated by a comparison operation between the row address RA and the address information in the table. When the row to be accessed next corresponds to the normal page, the memory controller may output the precharge command PRE according to a predetermined parameter tRAS or may output the precharge command PRE according to a predetermined parameter tRAS regardless of the received flag FLAG. In other words, among various operation parameters, at least some operation parameters that affect the memory characteristic are selected, and the operation parameters may be controlled according to whether or not the page to be accessed is weak.

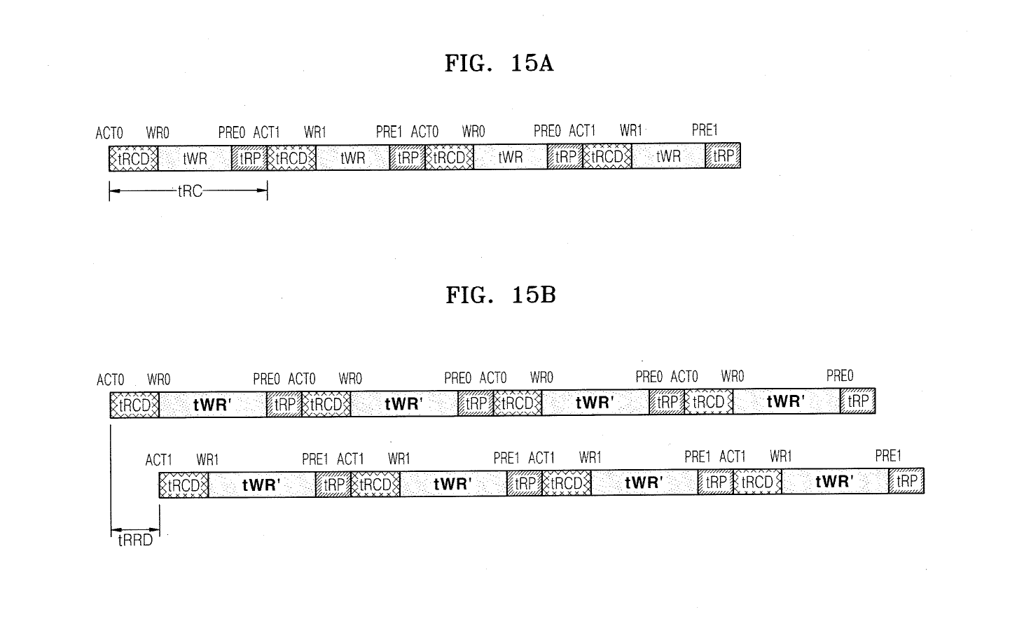

FIGS. 15A and 15B are diagrams showing an example of various commands and parameters that are applied to the semiconductor memory device, according to an example embodiment. FIG. 15A shows an example in which a bank interleaving method is applied, and FIG. 15B shows an example in which a sub-bank interleaving method is applied. It is assumed that the cell array of the semiconductor memory device includes a plurality of banks and each bank includes a plurality of sub-banks.

Referring to FIG. 15A, the plurality of banks may be operated in an interleaved manner. For example, the bank interleaving method may include an operation of any one bank (for example, a second bank) among the remaining banks after an operation of a first bank. Here, assuming that a first active command ACT0 is an active command for the first bank and a second active command ACT1 may be an active command for second bank, a write operation for a page of the first bank that is selected in correspondence to the first active command ACT0 is performed for a period of tWR, and a precharge operation for bit lines of the memory cells in the first bank is performed by the first precharge command PRE0. Thereafter, the first active command ACT0 for the first bank is applied again, and accordingly, the write operation and the precharge operation for the memory cell of the first bank are performed.

Meanwhile, when the second active command ACT1 for the second bank is applied, the write operation for the page of the second bank that is selected in correspondence to the second active command ACT1 is performed for the period of tWR, and the precharge operation for the bit lines of the memory cells in the second bank is performed by the second precharge command PRE1. Thereafter, the second active command ACT1 for the second bank is applied again, and accordingly, the write operation and the precharge operation for the memory cell of the second bank are performed.

In the bank interleaving method, the first active command ACT0 for the first bank and the second active command ACT1 for the second bank may be applied at an interval of tRRD time which is a row active to row active time between different banks. For example, word lines of the different banks may be simultaneously selected so as to access data, and accordingly, the tRRD time, which is an interval between the first active command ACT0 and the second active command ACT1, may be set to be relatively short.

Referring to FIG. 15B, an example is shown in which one bank includes a plurality of sub-banks and the sub-banks in any one bank are operated in an interleaved manner. For example, it is assumed that a command for activating first rows of the first and second banks belonging to the same bank is the first active command ACT0 and a command for activating the second row is the second active command ACT1.

In order to activate a row of the same sub-bank (for example, first sub-bank), the write operation and the precharge operation are sequentially performed after activating the first row and the second row. Meanwhile, the first active command ACT0 for activating the first row of the different sub-bank (for example, second sub-bank) may be provided at a shorter interval, and at least some in a tRCD period of the second sub-bank may be overlapped with active, record, and precharge periods. For example, FIG. 15B shows an example in which the tRCD period for the second sub-bank is overlapped with the precharge period for the first sub-bank.

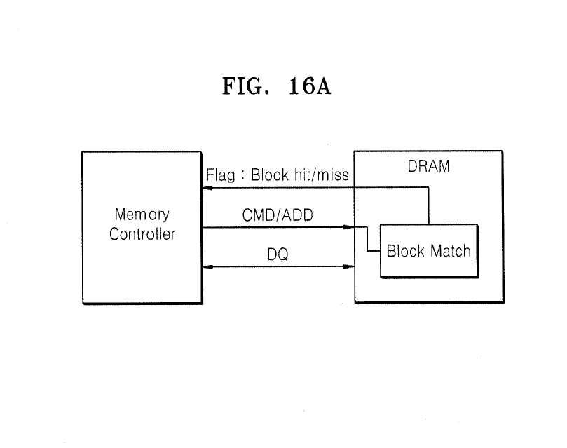

FIGS. 16A and 16B are diagrams showing another example of the transmission of the characteristic information and the control operation of the semiconductor memory device, according to an example embodiment of the inventive concepts. According to an example embodiment, DRAM may be used as the semiconductor device and information regarding a block (or sub-bank) is stored as the memory characteristic information.

Referring to FIG. 16A, the semiconductor memory device may form information of a block which a page corresponding to each address belongs to as a table and store the information. The address ADD from an outside source is compared with the stored information in response to a specific command CMD from the memory controller, and then it is determined whether or not a block to be accessed next and the existing activated block are the same. According to a result of the comparison, if the block to be accessed next and the existing activated block are the same, the flag FLAG representing a hit may be output to the memory controller, while if the block to be accessed next and the existing activated block are not the same, the flag FLAG representing a miss may be output to the memory controller.

Meanwhile, referring to FIG. 16B, the complex command including the precharge command and the active command is provided to the semiconductor memory device, and the bank address BA and the now address RA that are accompanied by the complex command are provided to the semiconductor memory device. In response to the complex command, the row address RA to be accessed next is compared with the block information in the table during a precharge operation, and the flag FLAG according to a comparison result is provided to the memory controller.

The memory controller may control a memory operation of the semiconductor memory device according to the received flag FLAG. For example, when the block to be accessed next and the existing activated block are the same, a relatively large tRCD may be applied until the column command such as the read/write command RD/WR is input, or the tRP which is time required for the precharge operation may be increased. In other words, since the rows included in the same block are activated, it is necessary to activate the internal active command after the relatively large tRP, and also the memory controller may output the column command RD/WR after the tRP and the tRCD that are relatively large. Accordingly, the tRP and the tRCD that are relatively large may be secured, and a relatively long write time may be secured by allowing the secured time to be converted into a write time tWR in the semiconductor memory device.

Meanwhile, when the block to be accessed next and the existing activated block are not the same, the memory controller may apply the tRP and the tRCD that are relatively small for controlling the semiconductor memory device. For example, in the case of different blocks, a row active is possible, and thus, the internal active command ACT for access of the next block after the precharge operation may be activated after a short tRP (or at the same time as the precharge operation). In other words, since an activation timing of the internal active command ACT may be controlled in the semiconductor memory device, a time may be allocated to various parameters (for example, tWR, tRP, tRCD, and the like) for a memory operation of the next block.

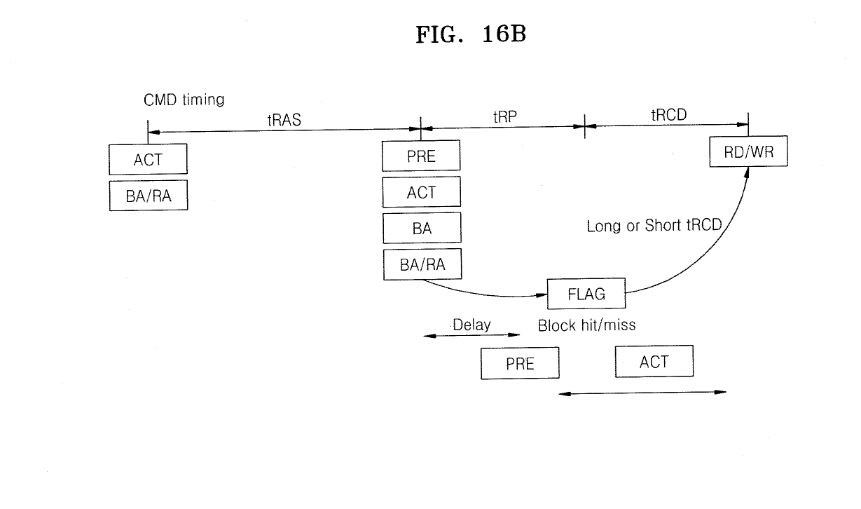

FIG. 17 is a diagram showing another example of the transmission of the characteristic information and the control operation of the semiconductor memory device, according to an example embodiment of the inventive concepts. FIG. 17 shows an example in which the characteristic information is output in response to the predetermined active command ACT instead of the complex command.

The active command ACT, and the bank address BA, and the row address RA that are accompanied by the active command ACT, are provided to the semiconductor memory device. By performing a comparison operation using the received row address RA, it is determined whether the block to be accessed next and the existing activated block are the same. As a determination result, the flag FLAG representing a hit or the flag FLAG representing a miss is output to the memory controller.

The semiconductor memory device may control an internal memory operation according to the determination result. For example, the semiconductor memory device may control an activation timing of the internal active command ACT according to whether the block to be accessed next and the existing activated block are the same. In addition, the memory controller may control an operation of the semiconductor memory device in response to the flag FLAG. For example, when the block to be accessed next and the existing activated block are the same, the semiconductor memory device may increase an amount of delay of the activation timing of the internal active command ACT, while when the block to be accessed next and the existing activated block are different from each other, an amount of delay of the activation timing of the internal active command ACT may be decreased. In addition, the memory controller may output the column command RD/WR by applying a relatively large tRCD when the block to be accessed next and the existing activated block are the same, while the memory controller may output the column command RD/WR by applying a relatively small tRCD when the block to be accessed next and the existing activated block are different from each other.

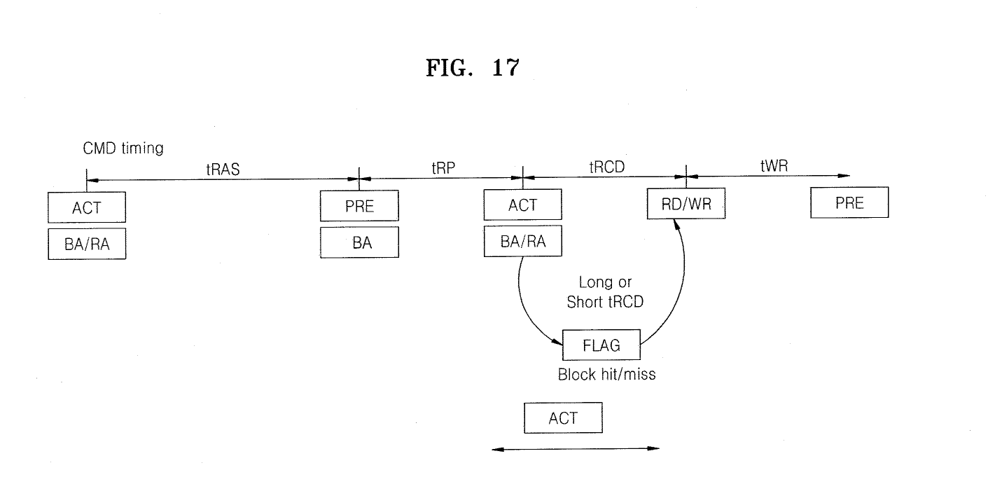

FIGS. 18A and 18B are diagrams showing another example of the transmission of the characteristic information and the control operation of the semiconductor memory device, according to an example embodiment of the inventive concepts. As an example of the semiconductor memory device, DRAM is used and address information regarding a weak page and information regarding a block are stored as the memory characteristic information.

Referring to FIG. 18A the address information regarding the weak page and the information of the block which a page corresponding to each address belongs to are formed as a table and are stored in the table included in the semiconductor memory device. It is determined whether or not the corresponding page is the weak page using the address ADD from the memory controller and whether the block to be accessed next and the existing activated block are the same. The flag FLAG according to a determination result may include two or more bit values, and accordingly, the flag FLAG may include information regarding at least two determination results.

Meanwhile, referring to FIG. 18B, various parameters of the semiconductor memory device may be controlled according to the determination result. For example, an address comparison operation is performed in response to a complex command PRE/ACT for requesting for precharge and active operations, and the flag FLAG according to the comparison result may be provided to the memory controller. In an identical or similar manner to the above-described embodiment, the parameters may be controlled based on whether or not the corresponding page is a weak page and/or whether the block to be accessed next and the existing activated block are the same.

For example, by controlling the activation timing of the internal active command ACT according to whether the block to be accessed next and the existing activated block are the same, sizes of the parameters such as the tRP and the tRCD may be controlled. Also, sizes of the parameters, such as the tRCD and the tWR, may be controlled based on whether or not the corresponding page is a weak, page.

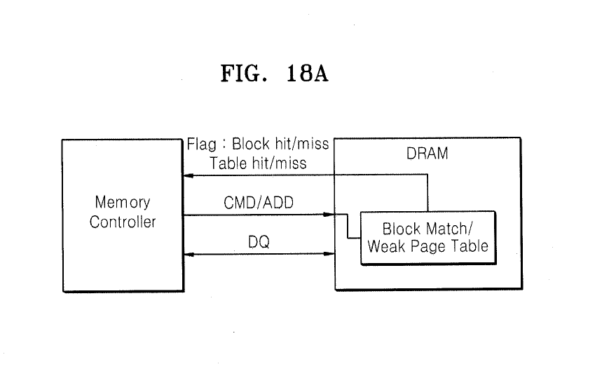

FIG. 19 is a flowchart showing an operating method of the semiconductor memory device, according to an example embodiment of the inventive concepts. As shown in FIG. 19, the semiconductor memory device may store address information regarding a weak area and information of a block (or sub-bank) which an area corresponding to each address belongs to, and may perform a comparison operation using the stored information in response to a specific command from an outside source. The comparison operation may be performed in response to at least one command among a plurality of commands. For example, it is assumed that the comparison operation is performed in response to a row command accompanied with a row address.

As shown in step S11, a row command is received. As shown in step S12, a row address accompanied with the row command is received. In various embodiments, the row command and the row address are received at the same time. In alternate embodiments, the row address may be received subsequent to receiving the row command (not shown). The semiconductor memory device includes the cell array including a plurality of areas, and an area to be accessed by the row address is selected. The area may be a page unit including the memory cells connected to the same word line.

As shown in step S13, the row address is compared with table information. When the row command and the row address are received, the row address (or internal row address passing through internal buffer) is compared with the information stored in the table. As shown in step S14, an information bit and/or a flag (e.g., the flag FLAG) is output according to a comparison result. The comparison result may represent whether the area to be currently accessed corresponds to the weak area and/or whether the block, which the area to be accessed next belongs to, is the same as the block that is previously activated. Additionally, the information bit and/or flag that is output may represent a memory characteristic (for example, data retention characteristic, write time characteristic, and/or the like) of the area to be accessed.

As shown in step S15, a timing-control command is received. The memory controller receives the flag and/or the information bit and controls various parameters related to the memory operation of the semiconductor memory device. For example, the controlling of the parameters may be performed by controlling a command output timing from the memory controller, and thus, the semiconductor memory device receives a timing-controlled command and performs a corresponding the memory operation.

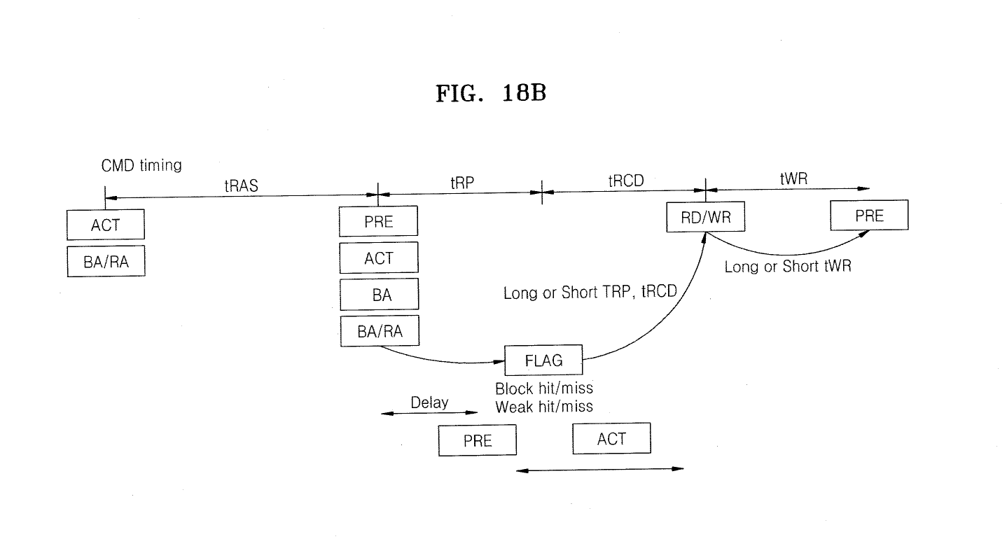

FIG. 20 is a flowchart showing an operating method of the semiconductor memory device, according to another example embodiment of the inventive concepts. In the embodiment shown in FIG. 20, an example is shown in which a comparison operation is performed in response to the complex command that is newly defined between the memory controller and the semiconductor memory device as a command that performs an address comparison operation.

As shown in step S21, a complex command is received. The complex command may be a command that requests to perform at least two operations. For example, the complex command may be a command that requests the precharge and active operations, may be a command that includes the auto precharge after read/write and active operations, or may be a command that includes other different operations. As shown in step S22, a row address accompanied with the complex command is received. In various embodiments, the complex command and the row address are received at the same time. In alternate embodiments, the row address may be received subsequent to receiving the complex command (not shown). The complex command may be accompanied with the row address in order to perform at least one operation, and the semiconductor memory device may generate at least one internal command for performing various memory operations by decoding the complex command.

The semiconductor memory device receives the complex command (as shown in step S21), and receives the row address accompanied by the complex command (as shown in step S22). When the complex command and the row address are received, the row address (or internal row address passing through internal buffer) is compared with the information stored in a table, as shown in step S23.

As shown in step S24, a flag or information bits are output. The flag and/or information bits may correspond to the weak area or correspond to the same block. As shown in step S25, an internal command and a control delay are generated. In various embodiments, the internal command of the semiconductor memory device and the control delay are generated and controlled based on the comparison result. For example, according to the decoding of the complex command, at least two internal commands may be generated, and a generation timing of the internal command or an amount of delay of the internal command may be controlled according to the comparison result.

As shown in step S26, a timing-controlled command is received. The memory controller receives the flag and/or information bits and controls various parameters related to the memory operation of the semiconductor memory device. For example, the semiconductor memory device receives a timing-controlled command from the memory controller and performs a corresponding memory operation.

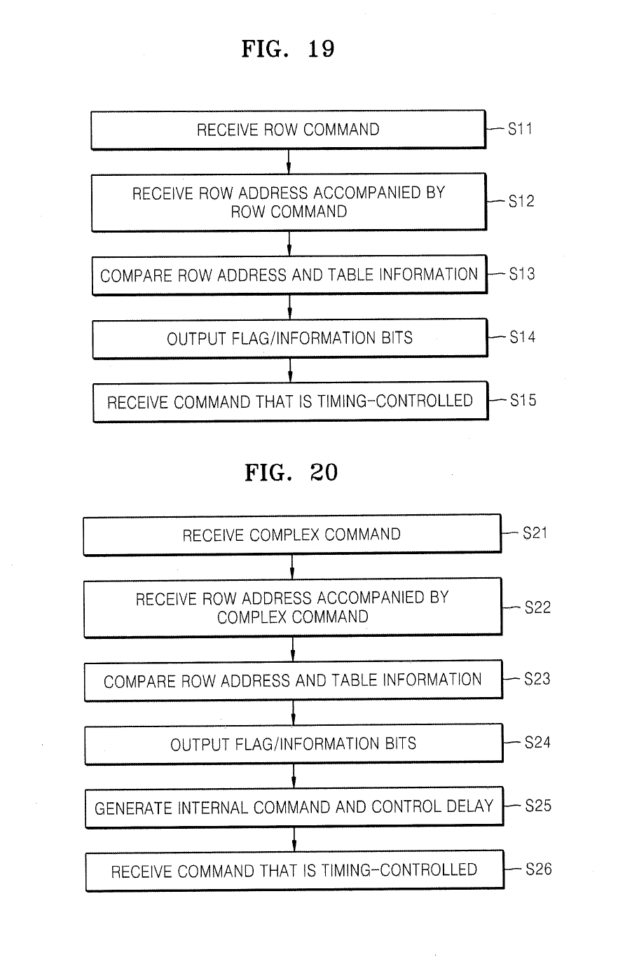

FIG. 21 is a flowchart showing an operating method of a memory controller, according to an example embodiment of the inventive concepts. FIG. 21 shows an example of an operation from a viewpoint of the memory controller in the memory system.

According to various embodiments, the memory controller may output a predefined command and newly defined complex commands to the semiconductor memory device. At least some of the output commands and complex commands are the row commands accompanied with the row address, and when the commands and complex commands are output, the flag/bit information may be received from the semiconductor memory device. For example, during the output of the row command, it is assumed that the flag/bit information is received from the semiconductor memory device.

As shown in step S31, the memory controller outputs both the row command and the row address to the semiconductor memory device. As shown in step S32, the flag or bit information is received. In various embodiments, the row address is compared with the information stored in the table inside the semiconductor memory device, and the memory controller receives the flag and/or bit information according to a result of the comparison. The memory controller may control generating a command inside the memory controller according to a value of the flag. For example, a generation timing of the command and an output timing to the semiconductor memory device may be controlled. Also, the bit information may represent the memory characteristic of the areas of the cell array of the semiconductor memory device, or may present the memory characteristic of the weak area among the areas of the cell array. As shown in step S33, the memory controller stores the bit information using storage means included therein.

As described above, the memory controller may perform the control operation according to the flag, or may determine the memory characteristic of the area to be accessed with reference to the bit information. Accordingly, as shown in step S34, the memory controller may manage the memory operation for each area of the semiconductor memory device.

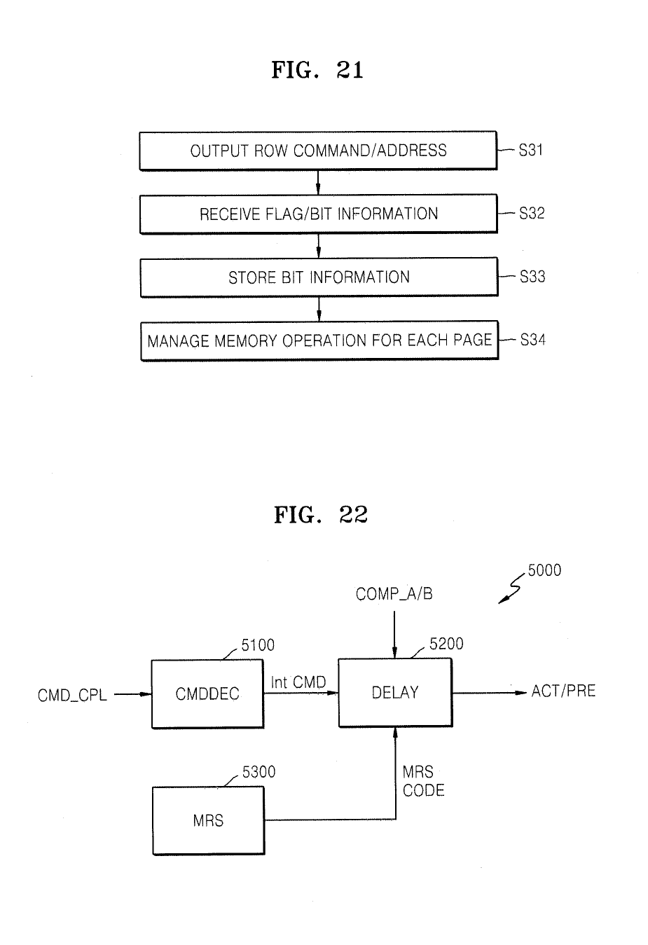

FIG. 22 is a block diagram showing an example in which delay of the internal command of the semiconductor memory device 5000 is controlled by a mode register set 5300 (MRS), according to an example embodiment of the inventive concepts.

As shown in FIG. 22, the semiconductor memory device 5000 includes a command decoder 5100, a delay unit 5200, and the MRS 5300. The command decoder 5100 may perform a decoding operation in an identical or similar manner to the above-described embodiments. For example, the command decoder 5100 may receive the complex command CMD_CPL from an outside source and decode the complex command CMD_CPL to generate the internal command Int CMD.

As in the above-described embodiments, on the basis of the result of the comparison COMP_A/B between the external address (for example, row address) and the information stored in the table (not shown), the internal command Int CMD may be delayed. The internal command Int CMD that is delay-controlled by the delay unit 5200 is a command (for example, ACT, PRE, or the like) to perform a memory operation and may be transmitted to other functional blocks inside the semiconductor memory device 5000.

The delay unit 5200 may include delay controllable circuit elements (not shown), and an amount of delay that is controlled by the delay unit 5200 may be set by the MRS 5300. During an initial operation of the semiconductor memory device 5000, an MRS code related to delay control is provided to the delay unit 5200 so as to set the amount of delay, and the delay unit 5200 may control a delay operation of the internal command int CMD according to the result of the comparison result COMP_A/B. According to alternate embodiments, an amount of delay of a plurality of steps may be set by the MRS code, and an amount of delay of the internal command Int CMD may be selected according to the comparison result COMP_A/B.

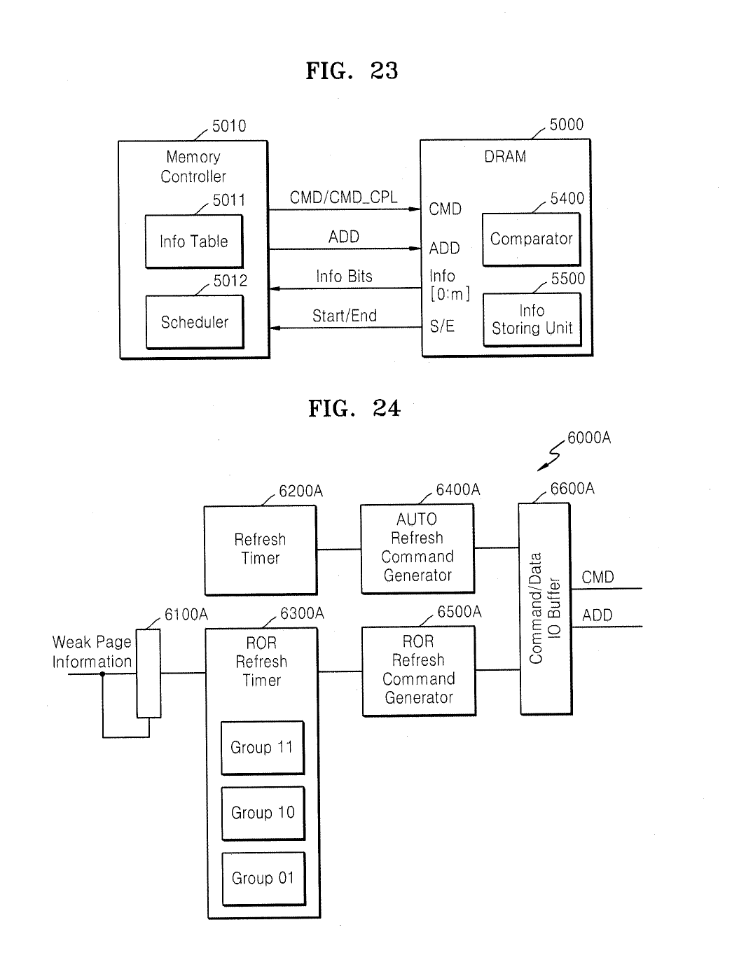

FIG. 23 is a block diagram showing an example of the semiconductor memory device that outputs the information bits, according to an example embodiment of the inventive concepts. For convenience of description, a memory controller 5010 is shown as well as the semiconductor memory device 5000.

The memory controller 5010 may receive the information bits Info Bits from the semiconductor memory device 5000 and include an information table 5011 that stores the information bits Info Bits. The memory controller 5010 may also include a scheduler 5012 for managing an operation of the semiconductor memory device 5000 with reference to information stored in the information table 5011. In addition, FIG. 23 shows a DRAM as the semiconductor memory device 5000. The semiconductor memory device 5000 includes an information storage unit 5500 that may store the weak address, the memory characteristic information, the block information, and other like areas of the cell array. The information storage unit 5500 also includes a comparator 5400 that may compare an address (for example, row address) from the memory controller 5010 and the information stored in the information storage unit 5500.

A flag or information bit that is determined according to a comparison result may be output via a predetermined pin that is included in the semiconductor memory device 5000. For example, the semiconductor memory device 5000 may include a separate information pin Info[0:m] for outputting the flag or information bit, and the flag or information bit according to the result of the comparison may be provided to the memory controller 5010 via the information pin Info[0:m]. Meanwhile, in order to provide a transmission timing of the information bit to the memory controller 5010, a signal Start/End that represents start or end of transmission of the flag or information bit may be output via a separate pin S/E.

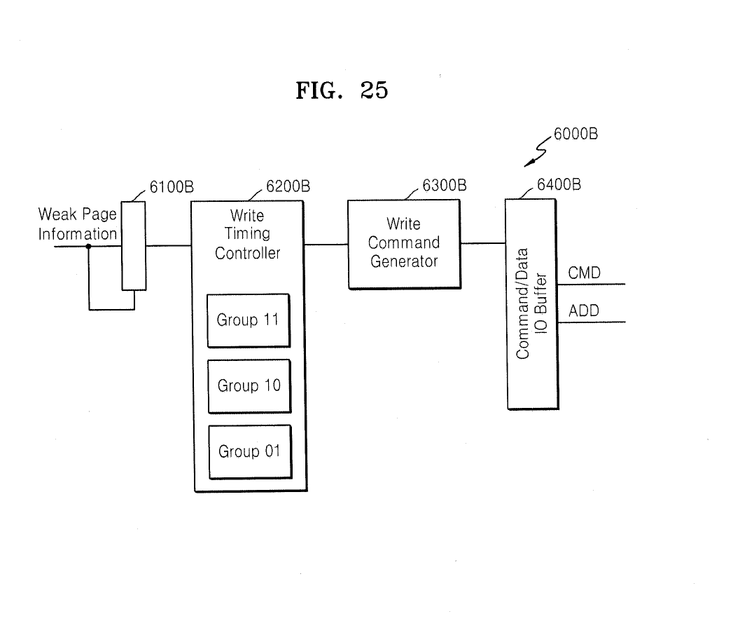

FIGS. 24 and 25 are block diagrams showing examples of memory controllers 6000A and 6000B respectively, according to an example embodiment of the inventive concepts. The memory controllers 6000A and 6000B of FIGS. 24 and 25 show an example of controlling the memory operation based on the flag or information bit from the semiconductor memory device.

As shown in FIG. 24, the memory controller 6000A includes an information table 6100A, and the information table 6100A may store memory characteristic information of the pages provided from the semiconductor memory device, for example, the characteristic information of the weak page. Also, the characteristic information may be grouped with a predetermined range of characteristic and stored grouped information.

The memory controller 6000A may include components for controlling a refresh operation for the semiconductor memory device. For example, the memory controller 6000A includes a refresh timer 6200A for controlling a timing of auto refresh and a refresh timer 6300A (for example, RAS Only Refresh (ROR) refresh timer) for controlling a timing of address designation refresh. In addition, the memory controller 6000A includes a command generation unit 6400A that may generate an auto refresh command under the control of the refresh timer 6200A. Memory controller 6000A includes an ROR refresh command generator 6500A that may generate an address designation refresh command under the control of the ROR refresh timer 6300A. Memory controller 6000A also includes an input and output (IO) buffer 6600A that may input and output a command, an address, or data.

The command generation unit 6400A generates the auto refresh command at a predetermined period and outputs the generated auto refresh command. In addition, the ROR refresh command generator 6500A generates the refresh command for designating an area to be refreshed and performing refresh in the area and outputs the generated refresh command. An area of the cell array in which ROR refresh is to be performed may be selected with reference to the information table 6100A. For example, the ROR refresh for designating an address is performed on an area with a relatively low data retention characteristic so as to increase the frequency of the refresh operations. The data retention characteristic may be classified into a plurality of groups. For example, four refresh operations may be performed for each refresh period (for example, 64 ms) with respect to an area belonging to a first group Group 11, three refresh operations may be performed for each refresh period with respect to an area belonging to a second group Group 1.0, and two refresh operations may be performed for each refresh period with respect to an area belonging to a third group Group 01. Although not shown in the drawing, a normal area (for example, normal page) may belong to a fourth group Group 00, and only the auto refresh may be performed in the normal area without performing the ROR refresh.

FIG. 25 shows an example of a write time control operation of a memory controller 6000B, according to an example embodiment. The memory controller 6000B includes an information table 6100B, and the information table 6100B may store information regarding a write time as the characteristic information of the areas of the cell array. In addition, the information table 6100B may store information of a write time of the weak area among the areas of the cell array, and the characteristic information may be grouped with a predetermined range of characteristic.

The memory controller 6000B includes a write timing controller 6200B, a write command generator 6300B, and a command/data input and output (IO) buffer 6400B. The write timing controller 6200B controls a write timing according to characteristics of areas (for example, weak areas) stored in the information table 6100B, and the write command generator 6300B generates a write command that is timing-controlled on the basis of a characteristic of an area to be accessed. For example, according to group information regarding the write time, the write timing controller 6200B controls the write timing such that the write operation is performed on the normal area for a write time of equal to or less than 10 ns and that the write operation is performed on the remaining weak areas for a longer time (for example, over 10 ns and equal to or less than 30 ns).

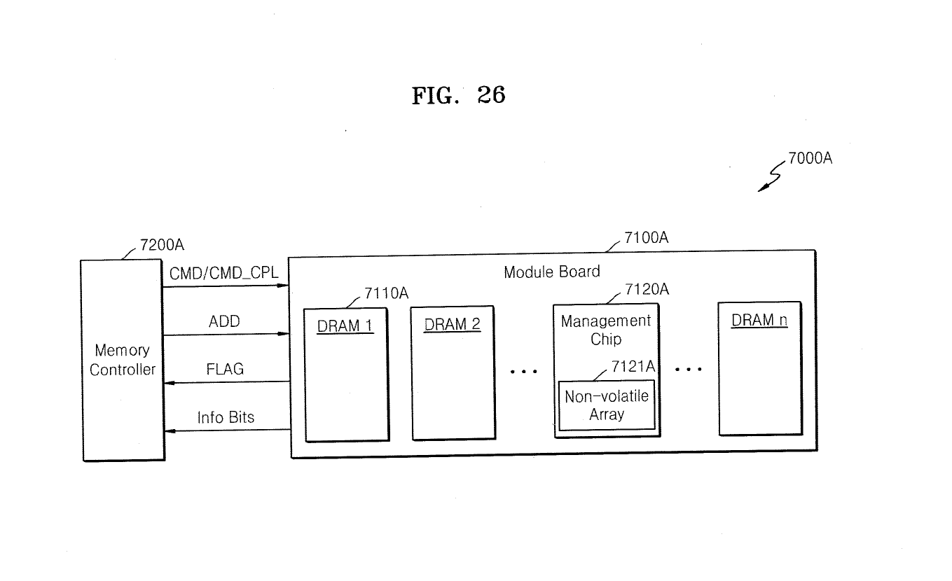

FIG. 26 is a block diagram showing an example of the memory module including the semiconductor memory device, according to an example embodiment of the inventive concepts. In the above-described embodiment, an example has been described in which the memory characteristic information is stored in the semiconductor memory device. However, a separate chip for memory management may be disposed on the memory module, and the memory characteristic information may be stored in the separate chip. In other words, a result of testing characteristics of the semiconductor memory device that is mounted on the memory module may be stored in a separate management chip on the memory module, and control of the memory operation according to the memory characteristic may be performed using an external controller or the management chip on the memory module. Accordingly, such embodiments of the inventive concepts may be applied to various types of memory modules, for example, a single in-line memory module (SIMM), a dual in-line memory module (DIMM), a small-outline DIMM (SO-DIMM), an unbuffered DIMM (UDIMM), a fully-buffered DIMM (FBDIMM), a rank-buffered DIMM (RBDIMM), a load-reduced DIMM (LRDIMM), a mini-DIMM, a micro-DIMM, and/or other like memory modules.

FIG. 26 is a block diagram showing an example of a memory module 7100A and a memory system 7000A, according to an example embodiment of the inventive concepts. FIG. 26 shows an example in which the embodiment of the inventive concepts is applied to an LRDIMM type memory module.

As shown in FIG. 26, the memory system 7000A includes a memory module 7100A and a memory controller 7200A. As shown, the memory module 7100A includes semiconductor memory device 7110A and a memory management chip 7120A that are mounted on the module board. DRAM chips DRAM1 to DRAMn each including a DRAM cell may be used as the semiconductor memory device 7110A, and the memory management chip 7120A includes a non-volatile array 7121A for storing information regarding characteristics of a cell array (not shown) of the semiconductor memory device 7110A. In the case of the LRDIMM type memory module, at least one rank for the memory operation may be defined. For example, the DRAM chips DRAM1 to DRAMn may be defined as different ranks.

As a result of one or more tests being performed using test equipment, a weak page or a memory characteristic of the cell array of the semiconductor memory device 7110A and pieces of information regarding a sub-block are stored in the non-volatile array 7121A. Additionally, the memory controller 7200A provides the command CMD/CMD_CPL and the address ADD to the memory module 7100A, and when the command CMD/CMD_CPL is a specific command, for example, a row command accompanied by a row address, the memory management chip 7120A compares the row address that is received together with the row command with the information stored in the non-volatile array 7121A and generates a result of the comparison. As described above, the comparison result may include the flag FLAG or the information bits Info Bits.

In addition, the memory controller 7200A may manage the memory operation according to the flag FLAG or the information bits Info Bits. For example, the memory controller 7200A may control various parameters related to the memory operation by controlling an output timing of the command CMD/CMD_CPL. In addition, a decoding operation and a delay operation of the command CMD/CMD_CPL may be performed by the management chip 7120A. Thus, an internal command that is delay-processed may be provided to the semiconductor memory device 7110A from the memory management chip 7120A.

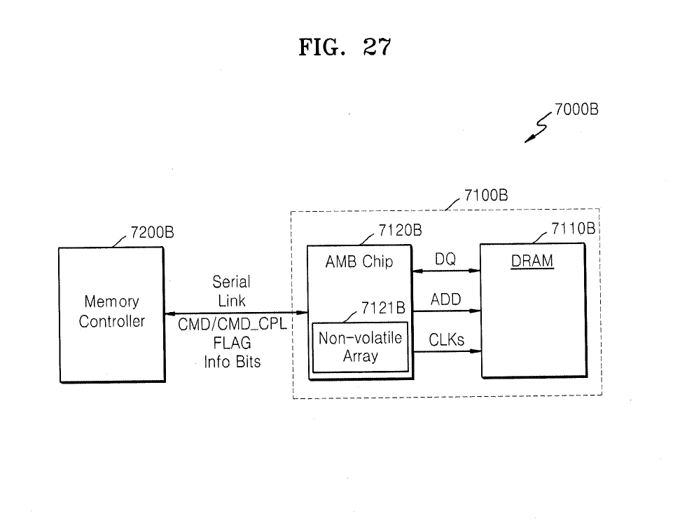

FIG. 27 is a block diagram showing another example of a memory module 7100B and a memory system 7000B, according to an example embodiment of the inventive concepts. FIG. 27 shows an example in which the embodiment of the inventive concepts is applied to a FBDIMM type memory module.

As shown in FIG. 27, the memory system 7000B includes a memory module 7100B and a memory controller 7200B, and the memory module 7100B includes at least one semiconductor memory device 7110B and an advanced memory buffer (AMB) chip 7120B. In the FBDIMM type memory module 7100B, the memory controller 7200B and the AMB chip 7120B inside the memory module 7100B are connected to each other in a point-to-pint fashion to perform serial communication. The AMB chip 7120B includes a non-volatile array 7121B for storing information regarding characteristics of a cell array (not shown) of the semiconductor memory device 7110B. Although FIG. 27 shows one memory module 71003 for convenience of description, since a number of the memory modules 7100B connected to the memory system 7000B may be increased according to an FBDIMM type module, the memory system 7000B may have large capacity. Additionally, since the FBDIMM uses a packet protocol, a high-speed operation is possible.

As a result of one or more tests being performed using test equipment, a weak page address or a memory characteristic of the cell array of each semiconductor memory device and pieces of information regarding a sub-block are stored in the non-volatile array 7121B of the AMB chip 7120B. When the command CMD/CMD_CPL received from the memory controller 72003 is a specific command, for example, a row command that is accompanied by a row address, the AMB chip 7120B compares the row address with the information stored in the non-volatile array 7121B and outputs the flag FLAG or information bits Info Bits according to a comparison result to the memory controller 7200B.

Various parameters related to a memory operation of the semiconductor memory device 7110B according to the result of the comparison may be controlled. As described above, the memory controller 7200B may control an output timing of the command CMD/CMD_CPL, or the AMB chip 7120E may perform a decoding operation and a delay operation of the command CMD/CMD_CPL and provide an internal command that is decoding-processing and delay-processed to the semiconductor memory device 7110B.

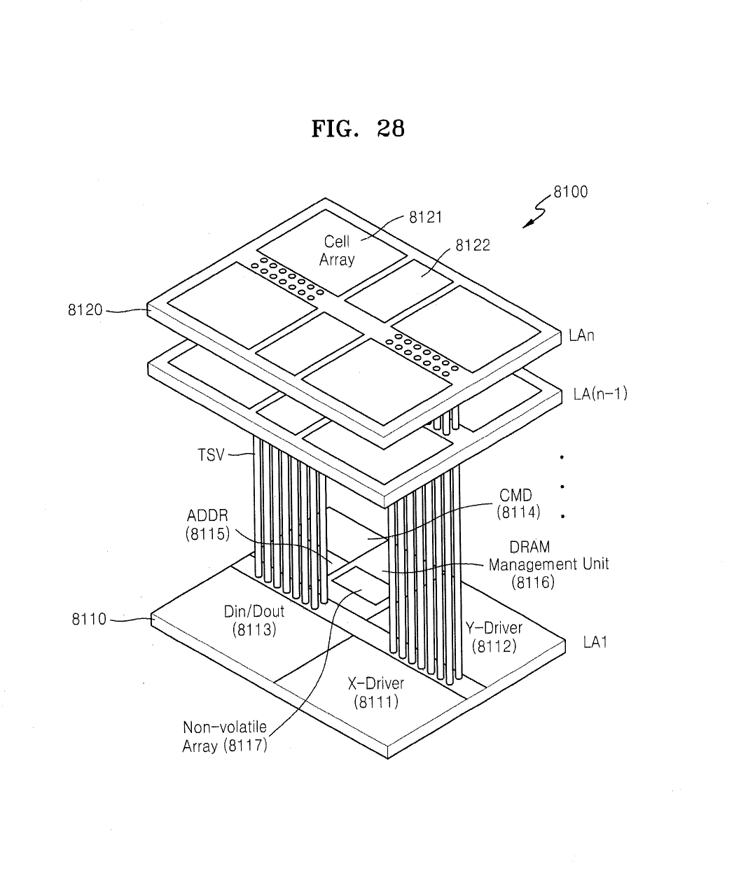

FIG. 28 is a structure diagram showing a semiconductor memory device 8100, according to another example embodiment of the inventive concepts. FIG. 28 shows an example in which the semiconductor memory device 8100 is configured by stacking a plurality of semiconductor layers.

As shown in FIG. 28, the semiconductor memory device 8100 may include a plurality of semiconductor layers LA1 to LAn. The semiconductor layers LA1 to LAn may be memory chips each including a DRAM cell, or alternatively, some of the layers LA1 to LAn may be master chips that perform interfacing with an external controller, and others may be slave chips that store data. In the example shown in FIG. 28, it is assumed that the semiconductor layer LA1 is a master chip and the other semiconductor layers LA2 to LAn are slave chips.

The plurality of semiconductor layers LA1 to LAn send and receive signals to and from each other via a through silicon via (TSV), and the master chip LA1 may communicate with an external memory controller (not shown) through a conductive device that is formed on an external surface thereof. Hereinafter, the configuration and operation of the semiconductor memory device 8100 will be described with an emphasis on a first semiconductor layer 8110 as a master chip and an n-th semiconductor layer 8120 as a slave chip.

The first semiconductor layer 8110 includes various circuits for driving cell arrays 8121 included in each slave chip. For example, the first semiconductor layer 8110 may include a row driver (X-Driver) 8111 for driving word lines of the cell arrays 8121, a column driver (Y-Driver) 8112 for driving bit lines, a data input and output unit Din/Dout 8113 for controlling input and output of data, a command decoder CMD 8114 for decoding the command CMD from an outside source, an address buffer ADDR 8115 that inputs an address from the outside source and buffers the address, and the like.

Also, the first semiconductor layer 8110 may further include a DRAM management unit 8116 for managing a memory operation of the slave chip. The DRAM management unit 8116, as described above, may include a non-volatile array 8117 for storing weak page addresses or memory characteristics of areas of the cell arrays 8121 and pieces of information regarding a sub-block. When a specific command, for example, a row command that is accompanied by a row address, is received from among commands received from the external controller, the DRAM management unit 8116 may compare the row address with the information stored in the non-volatile array 8117 and provide the flag FLAG or information bits Info Bits according to a comparison result to the external controller.

Meanwhile, the n-th semiconductor layer 8120 may include the cell arrays 8121, and peripheral circuit areas 8122 in which other peripheral circuits for driving the cell arrays 8121, for example, a row/column selection unit or a bit line sense amplifier (not shown) for selecting rows and columns of the cell arrays 8121, are disposed.

According to the example embodiment shown in FIG. 28, the flag FLAG or information bits Info Bits may be provided to the external controller according to the result of the comparison so that the external controller may control various parameters related to the memory operation according to the memory characteristics of the cell arrays 8121. Additionally, a decoding operation and a delay operation of a command may be controlled under the control of the DRAM management unit 8116.

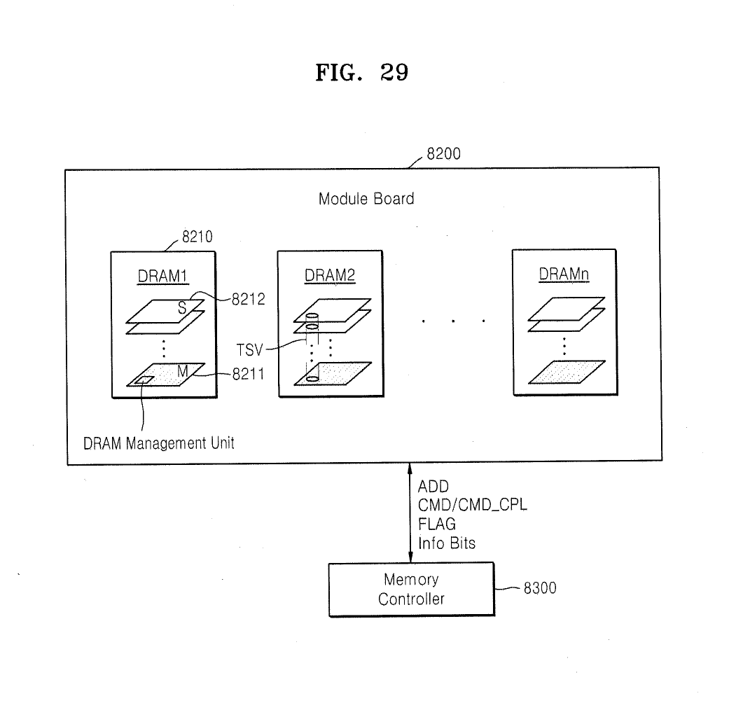

FIG. 29 is a diagram showing another example of a memory module 8200 including a semiconductor memory device 8210, according to an example embodiment of the inventive concepts. For convenience of description, a memory controller 8300, in addition to the memory module 8200, is also shown.

As shown in FIG. 29, the memory module 8200 includes at least one semiconductor memory device 8210 that is mounted on a module board. The semiconductor memory device 8210 may be configured as a DRAM chip, and each semiconductor memory device 8210 includes a plurality of semiconductor layers. The semiconductor layers include at least one master chip 8211 and at least one slave chip 8212. Also, as described above, the master chip 8211 may include a DRAM management unit that has anon-volatile array for storing memory characteristic information generated according to the embodiment of the inventive concepts. Signal transmission between the semiconductor layers may be performed through a TSV. The memory module 8200 may communicate the memory controller 8300 via a system bus, and thus, the command CMD/CMD_CPL, the address ADD, the flag FLAG, the information bits Info Bits, and the like are sent and received between the memory module 8200 and the memory controller 8300.

According to the memory module 8200 shown in FIG. 29, a separate chip for managing a memory operation is mounted on the module board; however, example embodiments are not limited thereto. According to various embodiments, some semiconductor layers of the semiconductor memory device 8210 may operate as master chips and the management unit for memory management may be disposed in the master chip. Accordingly, the degree of integration of the memory module 8200 may be improved.

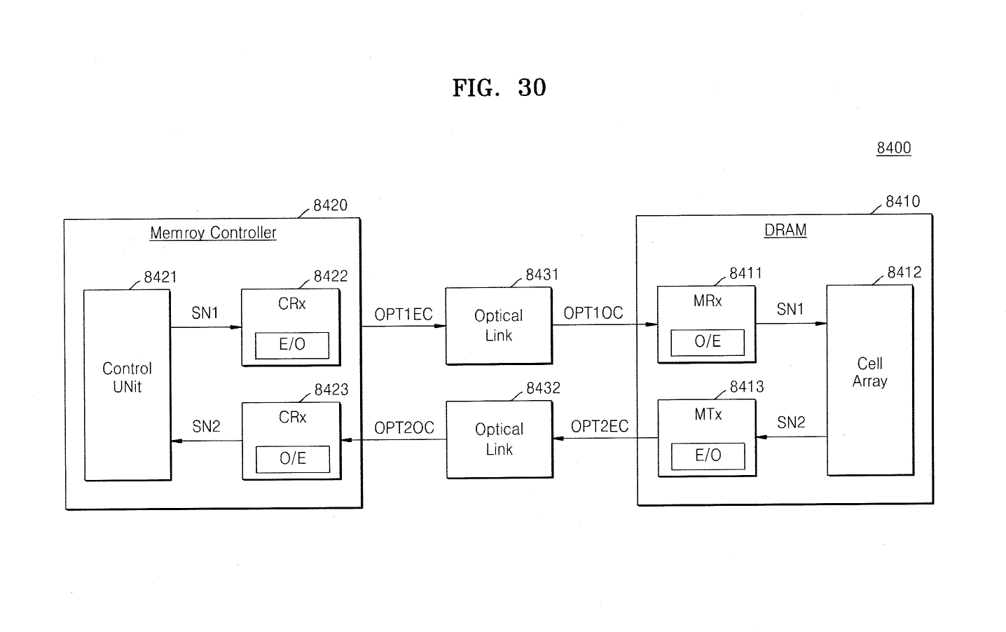

FIG. 30 is a diagram for describing a memory system 8400 including a semiconductor memory device 8410, according to another example embodiment of the inventive concepts. Referring to FIG. 30, the memory system 8400 includes optical link devices 8431 and 8432, a memory controller 8420, and the semiconductor memory device 8410. In FIG. 30, DRAM is shown as the semiconductor memory device 8410.

The optical link devices 8431 and 8432 interconnect the memory controller 8420 and the semiconductor memory device 8410 with each other. The memory controller 8420 includes a control unit 8421, a first transmission unit 8422, and a first reception unit 8423. The control unit 8421 transmits a first electrical signal SN1 to the first transmission unit 8422. The first electrical signal SN1 may include a command, a clock signal, an address, data, and the like that are transmitted to the semiconductor memory device 8410.

The first transmission unit 8422 includes an optical modulator E/O, and the optical modulator E/O converts the first electrical signal SN1 into a first optical transmission signal OT2OC and transmits the first optical transmission signal OT2OC to the optical link device 8431. The first optical transmission signal OTP1EC is transmitted by serial communication through the optical link device 8431. The first reception unit 8423 includes an optical demodulator O/E, and the optical demodulator O/E converts the second optical reception signal OPT2OC received from the optical link device 8430 into a second electrical signal SN2 and transmits the second electrical signal SN2 to a control unit 8420.

The semiconductor memory device 8410 includes a second reception unit 8411, a cell array 8412, and a second transmission unit 8413. The second reception unit 8411 includes the optical demodulator O/E, and the optical demodulator O/E converts a first optical reception signal OPT1OC from the optical link device 8430 into the first electrical signal SN1 and transmits the first electrical signal SN1 to the cell array 8412.

In the cell array 8412, write data is written in a memory cell in response to the first electrical signal SN1 or data that is read from the cell array 8412 is transmitted to the second transmission unit 8413 as the second electrical signal SN2. The second electrical signal SN2 may include a clock signal, read data, and the like that are transmitted to the memory controller 8420. The second transmission unit 8413 includes the optical modulator E/O that converts the second electrical signal SN2 into a second optical transmission signal OPT2EC and transmits the second optical transmission signal OPT2EC to the optical link device 8432. The second optical transmission signal OPT2EC is transmitted by serial communication through the optical link device 8432.

Although not shown in FIG. 30, according to various embodiments, the semiconductor memory device 8410 may perform various comparison operations in response to the command included in the optical transmission signal. Additionally, the semiconductor memory device 8410 may provide the optical transmission signal including the flag FLAG or the information bits Info Bits according to a comparison result to the memory controller 8420.

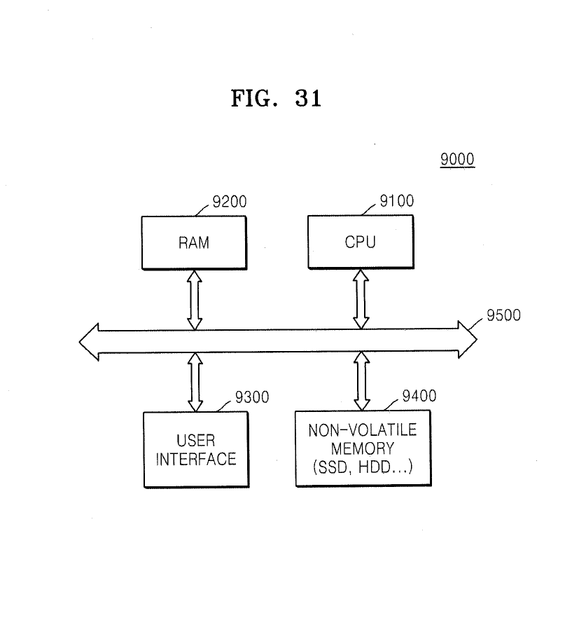

FIG. 31 is a block diagram showing a computing system 9000 in which a memory system is installed, according to an example embodiment of the inventive concepts. The semiconductor memory device of the inventive concepts may be installed as random access memory (RAM) 9200 in the computing system 9000 such as a mobile device or a desk-top computer. The semiconductor memory device installed as the RAM 9200 may be any of various ones that have been described in the embodiments described above. For example, any of various semiconductor memory devices that have been described in the above-described embodiments may be used as the RAM 9200, or alternatively, the RAM 9200 may be used in the form of a memory module. In addition, the RAM 9200 shown in FIG. 31 may be a device including a semiconductor memory device and a memory controller.

The computing system 9000 according to example embodiments of the inventive concepts includes a central processing unit (CPU) 9100, the RAM 9200, a user interface 9300, and non-volatile memory 9400, which are electrically connected to a bus 9500. A large-capacity storage device, such as a solid state drive (SSD), a hard disk drive (HDD), and/or other like computer readable storage media may be used as the non-volatile memory 9400.

In the computing system 9000, the RAM 9200, as in the above-described embodiments, may include the semiconductor memory device including the cell array for storing data, and the semiconductor memory device may be provided with a non-volatile array that stores the above-described memory characteristic information. In addition, when the RAM 9200 is configured as a memory module, a separate management chip may be included in the memory module, and the above-described non-volatile array may be disposed in the separate management chip.

According to the above-described semiconductor memory device, the memory module including the semiconductor memory device, and the method of operating the memory system and the semiconductor memory device, since the characteristic information of the cell array is stored and the characteristic information is provided to the memory controller with a sufficient time margin, various parameters related to the memory operation may be controlled, and additionally, an effect of the weak area on the memory operation may be reduced.

In addition, according to inventive concepts, the weak area of the semiconductor memory device may be effectively utilized without data loss, and a process yield of a semiconductor device may be improved even though DRAM process scaling is continuously improved.

While the inventive concepts have been particularly shown and described with reference to exemplary embodiments thereof, it will be understood that various changes in form and details may be made therein without departing from the spirit and scope of the following claims.

1. A semiconductor memory device comprising:
a cell array including a plurality of areas;
a command decoder configured to decode a command and generate an internal command; and
an information storage unit configured to store characteristic information of at least one of the plurality of areas,
the semiconductor memory device configured to receive a first command and a first row address accompanying the first command such that when the first command and the first row address accompanying the first command are received, characteristic information of an area corresponding to the first row address is provided to an outside device.

2. The semiconductor memory device of claim 1, wherein the cell array comprises a dynamic random access memory (DRAM) cell, and the areas are page units that are designated by a row address.

3. The semiconductor memory device of claim 1, wherein the characteristic information comprises address information that represents at least one of the areas of the plurality of areas having a relatively low memory characteristic as compared to a memory characteristic of at least one other area of the plurality of areas.

4. The semiconductor memory device of claim 3, wherein the characteristic information further comprises at least one piece of information from among a data retention characteristic and a write time characteristic of at least one of the areas of the plurality of areas corresponding to the address information.

5. The semiconductor memory device of claim 1, wherein the cell array comprises one or more banks, where each of the banks includes a plurality of sub-banks, and the characteristic information includes information regarding the sub-bank to which the area corresponding to the first row address belongs.

6. The semiconductor memory device of claim 1, wherein the characteristic information provided to the outside device includes at least one of,
first information representing whether the area corresponding to the first row address is a weak area,
second information regarding a memory characteristic of the area corresponding to the first row address, and
third information representing whether or not the sub-bank which the area corresponding to the first row address belongs to is the same as the sub-bank that was previously activated.

7. The semiconductor memory device of claim 1, wherein the first command is an active command accompanied by a row address.

8. The semiconductor memory device of claim 1, wherein the first command is a complex command that requests at least two memory operations, and the complex command is accompanied by a row address.

9. The semiconductor memory device of claim 8, wherein the complex command is a command for instructing at least one operation from among a write operation, a read operation, a precharge operation, and an active operation to be serially performed.

10. The semiconductor memory device of claim 8, wherein the first row address is an address for designating an area to be activated that is next to an area that is currently activated.

11. The semiconductor memory device of claim 1, further comprising:
a comparison unit that compares the first address with the information stored in the information storage unit and outputs a comparison result; and
a delay unit that receives the internal command and controls a delay of the internal command according to the comparison result.

12. The semiconductor memory device of claim 11, further comprising:
a mode register set (MRS) configured to set an amount of delay due to the delay unit.

13. The semiconductor memory device of claim 1, wherein the semiconductor memory device is configured to receive a second command according to an input timing signal controlled according to the characteristic information provided to the outside device.

14.-23. (canceled)

24. A memory system including a memory controller, the memory controller comprising:
a command generation unit configured to generate a command;
a flag receiving unit configured to receive a flag related to characteristic information of a memory, the flag receiving unit configured to receive the flag when a row command accompanying a row address is output; and
a scheduler configured to manage an operation for generating the command according to the received flag.

25. The memory system of claim 24, further comprising:
a semiconductor memory device having a cell array that includes a plurality of areas;
a command decoder configured to receive and decode the command to generate an internal command; and
an information storage unit configured to store characteristic information of at least one of the plurality of areas, the semiconductor memory device configured to compare the row address with the information stored in the information storage unit to generate the flag in response to the row command being received.

26. A memory system, comprising:
a memory controller and;
a memory module including a semiconductor memory device mounted on a memory board, the memory module configured to receive write data from the memory controller and to provide read data to the memory controller, the semiconductor memory device configured to,
receive a first command and a first row address accompanying the first command from the memory controller, and
provide characteristic information of an area corresponding to the first row address to the memory controller; and
wherein the memory controller is configured to provide control signals to the memory module for controlling the semiconductor memory device and configured to receive at least the characteristic information from the memory module.

27. The memory system of claim 26, wherein the memory module includes a serial-presence detect (SPD) and the characteristic information is stored in the SPD.

28. The memory system of claim 27, wherein the semiconductor memory device comprises:
a cell array including a plurality of areas; and
a command decoder configured to decode a command and generate an internal command,
the semiconductor device being configured to store characteristic information of at least one of the plurality of areas in the SPD.

29. The memory system of claim 28, wherein the characteristic information includes a flag, and the flag represents at least one characteristic of an area corresponding to a comparison of the received address with address information stored in the SPD.

30. The memory system of claim 28, wherein the memory controller is further configured to provide control signals to the memory module for controlling the SPD and configured to receive data stored in the SPD from the memory module.
